(19) United States
(12) Patent Application Publication
(10) Pub. No.: US 2026/0020407 A1
(43) Pub. Date: Jan. 15, 2026

(54) STACKED MONOCHROMATIC WAFERS WITH EDGE EMITTED LEDS FOR COLOR PIXEL DISPLAYS AND METHODS RELATED THERETO

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/960,702

(22) Filed: Nov. 26, 2024

Related U.S. Application Data
(60) Provisional application No. 63/671,635, filed on Jul. 15, 2024.

(51) Int. Cl. H10H 29/49; H10H 29/01; H10H 29/34; H10H 29/856

(52) U.S. Cl. CPC H10H 29/49; H10H 29/012; H10H 29/0364; H10H 29/34; H10H 29/856

(57) ABSTRACT

A display device comprises a substrate comprising one or more LEDs and one or more waveguides. Each LED is capable of emitting light in a first direction towards a corresponding waveguide. The corresponding waveguide is capable of reflecting received light in a second direction towards a viewing surface of the display.

### CROSS REFERENCE TO RELATED APPLICATION

This application claims the benefit of U.S. Provisional Patent Application No. 63/671,635, filed Jul. 15, 2024, which is hereby incorporated by reference herein in its entirety.

### FIELD

The present disclosure relates to display devices and methods of manufacturing the same.

### BACKGROUND

Micro light emitting diode (microLED, micro-LED, μLED, or μ-LED) displays may provide benefits of higher resolution and increased brightness when compared to conventional display technologies. A typical microLED display may be a heterogeneous system that integrates microLEDs and control devices manufactured using different substrates and different process flows. Unfortunately, current manufacturing processes used to assemble separately manufactured microLEDs and control devices into a single display e.g., robot-aided pick-and-place processes, may be prohibitively expensive and time-consuming for most commercial applications. Accordingly, there exists a need in the art for improved microLED displays and methods of manufacturing the same.

### SUMMARY

Embodiments herein provide for displays or displays devices formed from monochromatic wafers or substrates and methods for manufacturing the same. In some embodiments, the display or display device is an LED display comprising LEDs of any suitable size such as greater than about 500 microns in size, equal to or less than about 500 microns in size, greater than about 100 microns in size, equal to or less than about 100 microns in size, equal to or less than about 50 microns in size, or equal to or less than about 5 microns in size. In some embodiments, the display or display device is a microLED display (e.g., comprising LEDs equal to or less than about 100 microns, 50 microns, or 5 microns in size). Advantageously, the displays and manufacturing methods described herein may provide for reduced manufacturing costs and manufacturing time compared to conventional manufacturing. A wafer level process of monochromatic wafer stacking may be used to enable efficient fabrication of an integrated color pixel display from different wafers. The stacking and use of waveguides or reflecting blocks may enable a fill factor of about 50% or any suitable fill factor (e.g., above about 30%, or above about 40% or above about 45%) for the individual LEDs, increasing the fill factor from conventional display devices in which each color may have <30%, less than about 30%, about 20-25%, or less than about 20-25% of a pixel footprint.

One general aspect includes a display or display device comprising a substrate comprising one or more LEDs and one or more waveguides. Each LED is capable of emitting light in a first direction towards a corresponding waveguide. The corresponding waveguide is capable of reflecting the emitted light in a second direction towards a viewing surface of the display device. In some embodiments, the substrate comprises a multilayer stack with an opening formed therein and a waveguide disposed in the opening. The multilayer stack comprises an LED and light emitted from the LED is guided by the waveguide towards the viewing surface of the display device. In some embodiments, the substrate comprises a first multilayer stack with a first opening formed therein and a first waveguide disposed in the first opening. The first multilayer stack comprises a first LED. Light emitted from the first LED is guided by the first waveguide towards a viewing surface of the display device. The substrate may comprise a second multilayer stack overlaying the first multilayer stack. The second multilayer stack has a second opening formed therein and a second waveguide disposed in the second opening. The second multilayer stack comprises a second LED. Light emitted from the second LED is guided by the second waveguide towards the viewing surface of the display device.

In some embodiments, the display device may further include a third multilayer stack overlaying the second multilayer stack with a third opening formed therein. A third waveguide may be disposed in the third opening. The third multilayer stack may comprise a third LED and light emitted from the third LED may be guided by the third waveguide towards the viewing surface of the display device.

In some embodiments, the display device may further include another substrate overlaying the second multilayer stack with a third opening formed therein. A third waveguide may be disposed in the third opening. Light emitted by the first and second multilayer stack may exit a display device through the third waveguide.

Another general aspect includes a method of forming a display device as described in embodiments of the present disclosure. Generally, the method includes providing a first substrate comprising one or more LEDs capable of emitting light in a first direction towards an edge of the display device, where a viewing surface of the display device is in a second direction. The method includes providing a second substrate comprising one or more control devices. The method includes hybrid bonding the first substrate to the second substrate to electrically connect the one or more LEDs to the one or more control devices.

In some embodiments, the one or more LEDs comprise a plurality of LEDs. Providing the first substrate may include providing a multilayer stack and patterning the multilayer stack to form the plurality of LEDs. In some embodiments, providing the first substrate further comprises patterning the multilayer stack to form a plurality of waveguides capable of directing light emitted from the plurality of LEDs towards the viewing surface of the display device.

In some embodiments, the one or more LEDs further comprise a plurality of first LEDs and a plurality of second LEDs. Providing the first substrate may include providing a first multilayer stack, patterning the first multilayer stack to form the plurality of first LEDs, providing a second multilayer stack, and patterning the second multilayer stack to form the plurality of second LEDs. Providing the first substrate may further include patterning the first multilayer stack to form a plurality of first waveguides capable of directing light emitted from the first LEDs towards the viewing surface of the display device, and patterning the second multilayer stack to form a plurality of second waveguides capable of directing light emitted from the second LEDs towards the viewing surface of the display device.

In some embodiments, providing the first substrate further comprises attaching the first multilayer stack to the second multilayer stack. In some embodiments, attaching the first multilayer stack to the second multilayer stack comprises directly bonding a dielectric layer of the first multilayer stack to a dielectric layer of the second multilayer stack to form direct dielectric bonds. In some embodiments, attaching the first multilayer stack to the second multilayer stack comprises hybrid bonding conductive features disposed in a dielectric layer of the first multilayer stack to conductive features disposed in a dielectric layer of the second multilayer stack to form direct metal bonds and direct dielectric bonds.

In some embodiments, patterning the first multilayer stack to form the first waveguides comprises forming first openings on a first surface in the first multilayer stack, depositing a first dielectric layer in the first openings, depositing a first reflective layer or a first stack of layers on the first dielectric layer in the first openings, depositing a second dielectric layer on the first reflective layer to fill the first openings, forming second openings on a second surface in the first multilayer stack to expose the first dielectric layer, the second surface being opposite the first surface in the first multilayer stack; and depositing a third dielectric layer on the first dielectric layer to fill the second openings.

In some embodiments, patterning the second multilayer stack to form the second waveguides comprises forming third openings on a first surface in the second multilayer stack, depositing a fourth dielectric layer in the third openings, depositing a second reflective layer or a second stack of layers on the fourth dielectric layer in the third openings, depositing a fifth dielectric layer on the second reflective layer to fill the third openings, forming fourth openings on a second surface in the second multilayer stack to expose the fourth dielectric layer, the second surface being opposite the first surface in the second multilayer stack, and depositing a sixth dielectric layer on the fourth dielectric layer to fill the fourth openings.

In some embodiments, the first reflective layer forms a first mirror or the first stack of layer forms a first dichroic optical element. In some embodiments, the second reflective layer forms a second mirror or the second stack of layers form a second dichroic optical element.

In some embodiments, attaching the first multilayer stack to the second multilayer stack forms a workpiece, and the method further comprises providing a third multilayer stack, patterning the third multilayer stack to form a plurality of third LEDs, and attaching the third multilayer stack to the workpiece. The third multilayer stack may be attached to the workpiece by direct bonding or hybrid bonding. In some embodiments, attaching the third multilayer stack to the workpiece comprises directly bonding a dielectric layer of the third multilayer stack to a dielectric layer of the workpiece to form direct dielectric bonds. In some embodiments, attaching the third multilayer stack to the workpiece comprises hybrid bonding conductive features disposed in a dielectric layer of the third multilayer stack to conductive features disposed in a dielectric layer of the workpiece to form direct metal bonds and direct dielectric bonds.

In some embodiments, attaching the first multilayer stack to the second multilayer stack forms a workpiece, and the method further comprises providing a third substrate comprising a plurality of third LEDs, and attaching the third substrate to the workpiece. In some embodiments, attaching the third substrate to the workpiece comprises directly bonding a dielectric layer of the third substrate to a dielectric layer of the workpiece to form direct dielectric bonds. In some embodiments, attaching the third substrate to the workpiece comprises hybrid bonding conductive features disposed in a dielectric layer of the third substrate to conductive features disposed in a dielectric layer of the workpiece to form direct metal bonds and direct dielectric bonds.

In some embodiments, the methods, systems, and apparatus (e.g., displays) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1D schematically illustrate example views of a display device, according to some embodiments;

FIG. 2 schematically illustrates an example cross-section of a pixel configuration in a display device, according to some embodiments;

FIGS. 3A-3B schematically illustrate example views of a pixel configuration in a display device, according to some embodiments;

FIG. 4 schematically illustrates aspects of a method of forming a layer of a display device, according to some embodiments;

FIG. 5 schematically illustrates examples of inter-pixel deep trench isolations (DTI) in a display device, according to some embodiments;

FIGS. 6A-6D schematically illustrate examples top views of a display device, according to some embodiments;

FIGS. 7A-7B schematically illustrate example top views of a display device, according to some embodiments;

FIG. 8 schematically illustrates a cross-section of a pixel configuration in a display device, according to some embodiments;

FIG. 9 schematically illustrates an example view of pixel configuration in a display device, according to some embodiments; and

FIGS. 10A-10B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for improved (e.g., more efficient or high-volume) manufacturing of displays (e.g., display devices, LED displays, LED display devices, micro-LED displays, micro-LED display devices) using stacked and bonded monochromatic wafers or substrates. Embodiments herein may provide for a display comprising at least one stackable layer of edge-emitting LEDs and methods for forming the same. The display may further comprise one or more layers of edge-emitting LEDs and/or one or more layers of surface-emitting LEDs that are attached to (e.g., directly bonded, hybrid bonded) the at least one layer of edge-emitting LEDs. A display device comprising at least one stackable layer of edge-emitting LEDs and corresponding waveguides may enable increased surface area of an active layer per pixel, allowing for greater light output and increase in luminance over conventional displays.

The integration of microLED technology in displays may offer significant benefits in terms of resolution, energy efficiency, brightness, and overall display performance. The ability to precisely control each microLED may allow for better luminous flux with a higher dynamic range and a broader spectrum of colors, leading to more vibrant, bright, and lifelike images, which may be beneficial for applications requiring high-definition visuals, such as advanced televisions, smartphones, wearable devices, automotives, and virtual/augmented reality devices. Additionally, the energy efficiency of microLEDs may translate into longer battery life for portable devices and lower power consumption for larger displays. The versatility of microLED technology extends to the potential for flexible and transparent displays, opening new avenues for innovative design and application in various fields, ranging from consumer electronics to specialized industrial and medical equipment. MicroLED displays may have higher brightness, increased power efficiency, longer lifetime, more durability, and may be more suitable for stretchable and transparent display applications over light-crystal displays (LCD) or organic light emitting diode (OLED) displays.

However, microLED displays may be costly to fabricate and may have time-consuming manufacturing methods such as robot-aided pick-and-place processes used to transfer microLED chips from LED wafer(s) to a display substrate. As an example, a microLED ultra-high density (UHD) 4K RGB (red, green, blue) display may comprise about or at least 25 million microLEDs (e.g., about 8.3 million pixels with each pixel having at least a red microLED, a blue microLED, and a green microLED), and a die bonding machine may transfer between 5 to 10 microLEDs per second, taking approximately 700 hours to transfer 25 million microLED chips for a single display. Accordingly, there exists a need in the art for improved microLED displays with a streamlined mass transfer processes and the methods of manufacturing the same.

LEDs may be fabricated at a first wafer (e.g., 150 mm wafers) and integration with silicon at a second wafer (e.g., 300 mm wafer) may be challenging. Reconstituting LED and silicon separately may help integration and assembly. Different colored LEDs may be fabricated on different wafers (e.g., red LED wafer, green LED wafer, blue LED wafer), singulated (e.g., diced) into individual LEDs (e.g., red LEDs, green LEDs, and blue LEDs), and then transferred (e.g., picked and placed, bonded) onto a display backplane (e.g., transistor matrix, silicon or TFT backplane) to form a display.

In some approaches, R, G, and B wafers may be patterned and vertically stacked. For example, a wafer of patterned blue LEDs may be stacked on top of a wafer of patterned green LEDs, and the wafer of patterned green LEDs may be stacked on top of a wafer of patterned red LEDs. However, the vertically stacked wafers may have LEDs (e.g., surface emitting LEDs) that are overlapping when emitting light, which may be inefficient considering brightness per unit area. The LEDs or substrate may not be transparent to light, and vertically overlapping LEDs may block the light from LEDs underneath. For example, a red LED on bottom may only emit light in areas not occupied by overlapping green and blue LED, and green LED in the intermediate position may only emit light in areas not occupied by overlapping blue LED.

In some approaches, R, G, and B wafers may be reconstituted and vertically stacked. For example, each R, G, and B wafer may be singulated and reconstituted into corresponding R, G, and B reconstituted substrates (e.g., each reconstituted substrate may comprise a plurality of single color LEDs). In the vertically stacked reconstituted substrates, the LEDs may be offset so they are not vertically overlapping and do not block light from LEDs underneath. However, reconstituting and vertically stacking R, G, and B wafers may result in inefficient use of a pixel area. For example, each R, G, and B LED (e.g., surface-emitting LEDs) may have about 30% or less or about 20-25% or less in fill factor (e.g., active area of each LED to a pixel area or footprint). Having a lower fill factor may effectively reduce the brightness of the pixel.

Advantageously, the displays or display devices (e.g., microLED displays) and manufacturing methods described herein may provide for reduced manufacturing costs and manufacturing time compared to conventional pick-and-place manufacturing. Use of edge-emitting LEDs and corresponding waveguides may increase a size of LEDs in a pixel, thereby increasing the brightness emitted from each pixel.

A size of a pixel for a display may vary depending on the application-about 5 microns or less than about 5 microns, less than about 10 microns, or about 5-10 microns for augmented reality/virtual reality (AR/VR) or mixed reality (MR) applications, about 30-50 microns for watches, about 40-60 microns or about 50-70 microns for cellphones, about 300-400 microns or about 350 microns for computer monitors and screens, about 500-1000 microns or greater than about 0.5 mm for televisions. The size of the source LED occupying the pixel may not match the size of the pixel itself. Light emitted from a small LED can fill all of the pixel area of a large pixel and help create a continuous image. The ratio of pixel size to LED size can range from about 1.5 to 3 in AR/VR or MR applications (e.g., pixel size is about 1.5×LED size to about 3× LED size) to over 100 (e.g., pixel size greater than about 100×LED size) in a television application. The smaller the ratio (e.g., area of pixel to area of LED), the larger the LED fill factor, and more light would be output. A larger LED fill factor indicates higher brightness requirement of the application. Different applications have varying luminous flux density requirement (e.g., brightness requirement). While AR/VR applications require extremely bright light so the projected images may be visible in extreme conditions (e.g., bright daylight), brightness requirements may be less stringent for other applications such as monitors and TVs in which the screens which have a larger viewing distance (e.g., are comparatively far away from an eye of a viewer). In some embodiments, a pixel comprises a plurality of source LEDs (e.g., an RGB pixel comprises 3 LEDs per pixel, an RGBG (red, green, blue, green) pixel comprises four LEDs per pixel), and a control circuit may be shared by several pixels.

The shorter the distance between the screen and viewer (e.g., an eye of a viewer) in an application, the smaller the pixel size requirement to provide a continuous image without a visible gap between the neighboring pixels. In AR/VR or MR applications, where a display may be about 1-2 cm from an eye of a viewer, pixel sizes may be typically less than 5 microns, and there may be a challenge to achieve high pixel density and to ensure uniformity and brightness of pixels for an immersive visual experience. Such applications may require smaller pixels (e.g. <5-10 μm) and larger fill factor. The embodiments herein describe approaches which may enhance the density and uniformity of the pixels and/or improve the light emission efficiency. In television applications where pixel sizes can be greater than 0.5 mm (e.g., the screen is typically several feet away from the eye of a viewer; hence larger pixel and smaller LED fill factor would work), a stacked LED structure may be used for larger pixel requirements. In some embodiments, a pixel may include additional LEDs (e.g., other than RGB, such as white, cyan, magenta, etc.) to achieve an enhanced color gamut beyond the standard RGB and/or to add more light emission to improve brightness.

In some embodiments, dielectrics specifically tuned to certain color spectrums may be used within the optical path of the display for improved efficiency. Suitable materials for these dielectrics may include polystyrene, cyclic olefin polymer/cyclic olefin copolymers, polycarbonate, PMMA (Acrylic), or Ultraviolet Acrylic. These materials are known for their high transmission in the visible spectrum, which is relevant for improved efficiency and functionality of an RGB display.

As described below, semiconductor substrates, display substrates, or micro-LED display substrates herein generally have a “device side,” e.g., the side on which semiconductor device elements are fabricated, such as transistors, resistors, capacitors, micro-LEDs, driver circuits, and interconnects, and a “backside” that is opposite the device side. The term “active side” or “display surface” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

In some embodiments, the term “substrate” herein refers to an element of a device made of silicon or other semiconductor materials. Alternatively, or additionally, the substrate includes other semiconductor materials such as germanium, gallium arsenic, or other suitable semiconductor materials. In some embodiments, substrate may further include other features such as various doped regions, a buried layer, and/or an epitaxy layer. Moreover, in some embodiments, substrate is made of an alloy semiconductor such as silicon germanium, silicon germanium carbide, gallium arsenic phosphide, or gallium indium phosphide. Furthermore, the substrate may be a semiconductor on insulator such as silicon on insulator (SOI) or silicon on sapphire.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

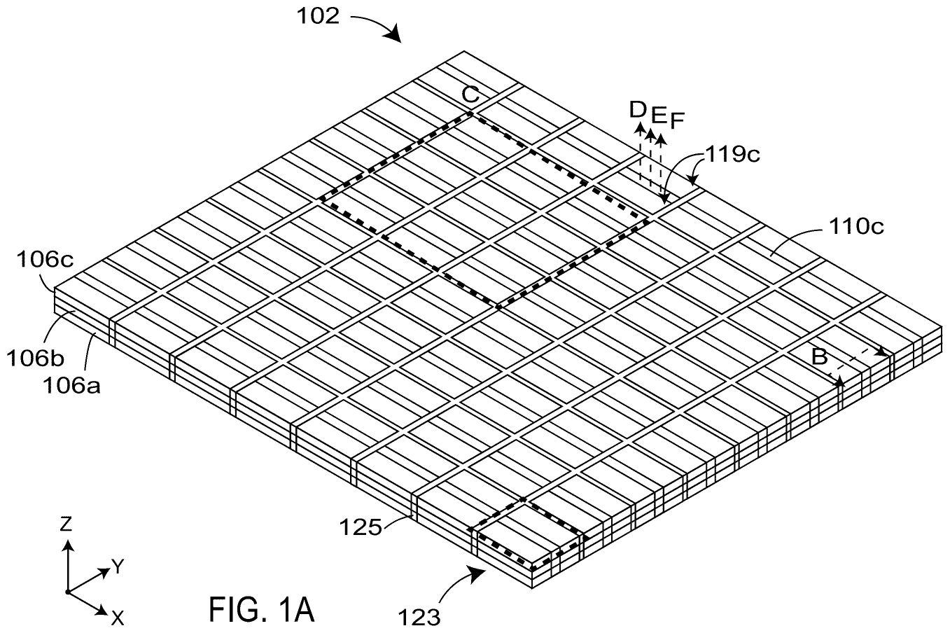

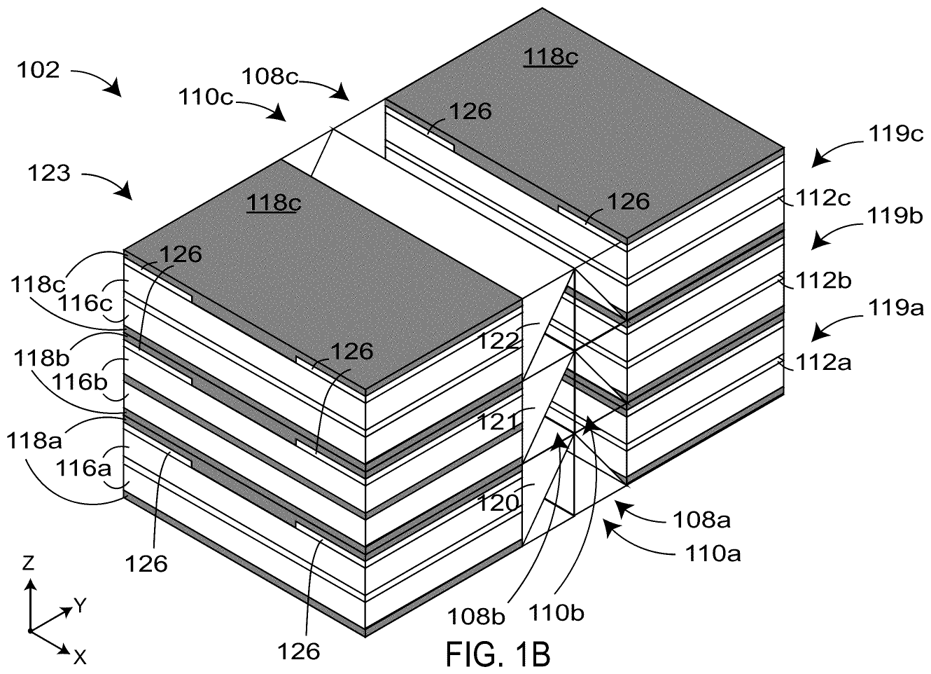

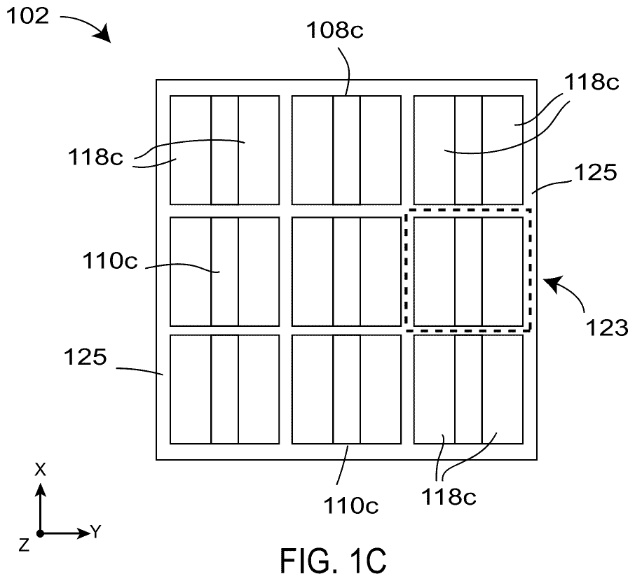

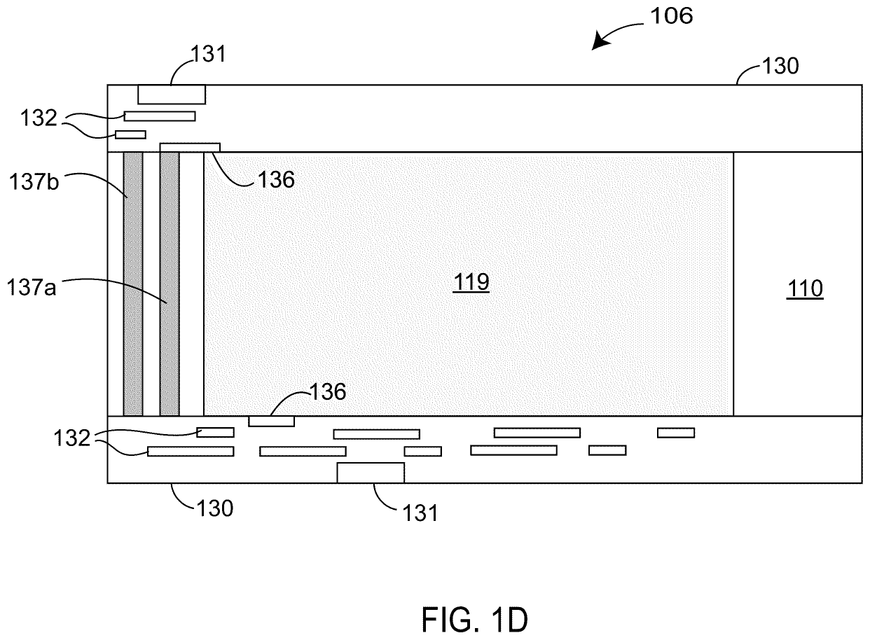

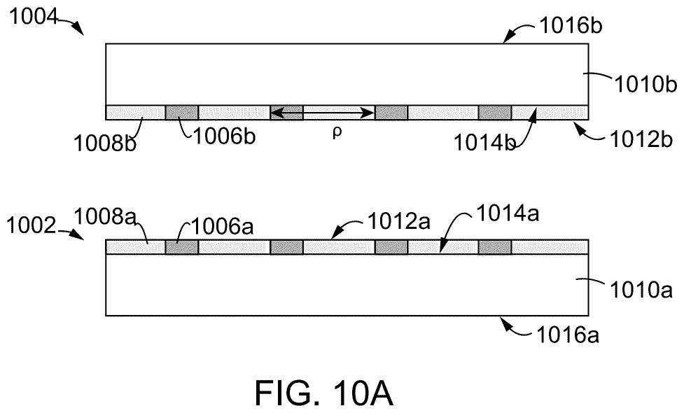

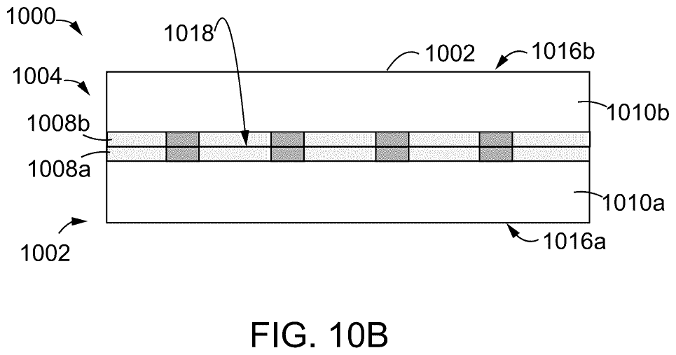

FIGS. 1A-1D, 2, 3A-3B, 4, 5, 6A-6D, 7A-7B, 8, and 9 schematically illustrate various embodiments of a display. In some embodiments, the display (e.g., display 102, display 202, display 302, display 802, display 902, or any suitable display described throughout the present disclosure) may be a microLED display and comprise microLEDs, with sizes equal to or less than about 100 microns, 50 microns, or 5 microns. FIGS. 10A-10B illustrate a hybrid bonding method for bonding substrates (e.g., substrates comprising LEDs to substrates comprising LEDs, substrates comprising LEDs to substrates comprising control devices and/or LEDs).

In some embodiments, the display (e.g., display 102, display 202, display 302, display 802, display 902, or any suitable display described throughout the present disclosure) may be an LED display and comprise LEDs greater than about 500 microns in size or greater than about 100 microns in size. In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

A display may comprise any suitable number of pixels (e.g., one or more pixels, a plurality of pixels). Although a display (e.g., display 102, display 202, display 302, display 802, display 902, or any suitable display described throughout the present disclosure) may show a specific number of pixels (e.g., one, three, nine, sixty four, etc.), in some embodiments the display may comprise any suitable number of pixels (e.g., hundreds, thousands, millions, 1 megapixel (MP, one million pixels), 4MP, 8MP, 50MP, 100MP, etc.) in any suitable arrangement of pixels (e.g., arranged in an XY grid, etc.).

A pixel may comprise any suitable number, shape, and color of sub-pixels or LEDs (e.g., one, two, three or more LEDs). Although a pixel (e.g., pixel 123, pixel 223, pixel 323, pixel 823, pixel 923 or any suitable pixel described in the present disclosure) may show a specific number of sub-pixels (e.g., two, three), in some embodiments the pixel may have any suitable number of sub-pixels or LEDs (e.g., one, two, four, five or more, etc.). Although the sub-pixels or LEDs are shown as similarly shaped rectangles, in some embodiments the sub-pixels or LEDs may be of any suitable shape. In certain embodiments, advancements in color conversion layers (e.g., colored phosphors, quantum dot layers, etc.) may permit the addition of a fourth color, like a green variant or cyan, to enhance the color gamut. In some embodiments, a pixel may comprise three sub-pixels (e.g., red sub-pixel, blue sub-pixel, and green sub-pixel). In some embodiments, a pixel may comprise four sub-pixels comprising a red LED, a blue LED, and two green LEDs. In some embodiments, LEDs of a pixel (e.g., pixel 123, pixel 223, pixel 323, pixel 823, pixel 923 or any suitable pixel described in the present disclosure) may also be electronically connected to a control device (e.g., integrated circuit, readout integrated circuits, etc.).

FIG. 1A schematically illustrates an isometric view of a display 102 (e.g., display device, micro-LED display), according to some embodiments. FIG. 1A shows the display 102 comprising three multilayer stacks (e.g., layers, substrates, wafers, or chips): a first multilayer stack 106a, a second multilayer stack 106b, and a third multilayer stack 106c. A third multilayer stack 106c may be disposed on a second multilayer stack 106b, and the second multilayer stack 106b may be disposed on the first multilayer stack 106a. Each of the multilayer stacks 106a-c may be bonded (e.g., directly bonded, hybrid bonded) to an adjacent multilayer stack 106a-c. Although FIG. 1A depicts three multilayer stacks, a display 102 can have one or more of such multilayer stacks (e.g., 1 multilayer stack, 2 multilayer stacks, 4 multilayer stacks, etc.). For example, display 102 may comprise one substrate (e.g., 1 multilayer stack) comprising one or more LEDs and one or more waveguides, where each LED is capable of emitting light in a first direction towards a corresponding waveguide and the corresponding waveguide is capable of reflecting the emitted light in a second direction towards a viewing surface of the display. In some embodiments, each LED may emit light in a first direction towards an edge of a display (e.g., along the y-axis, in any suitable direction in an emission plane of the multilayer stack or x-y plane, or any suitable direction), and the corresponding waveguide may be capable of reflecting the emitted light in a second direction (e.g., along the z-axis, a direction orthogonal to the first direction or emission plane, any suitable direction different from the first direction or at an angle to the first direction or emission plane, etc.) towards a viewing surface of the display. A method of forming a display device (e.g., the display 102) having at least one multilayer stack may comprise attaching (e.g., direct bonding, hybrid bonding) a first substrate comprising one or more LEDs capable of emitting light in a first direction towards an edge of the display device, where a viewing surface of the display device is in the second direction, to a second substrate comprising one or more control devices to electrically connect the one or more LEDs to the one or more control devices. In some embodiments, the first substrate may be a multilayer stack, a wafer of edge-emitting LEDs, etc.

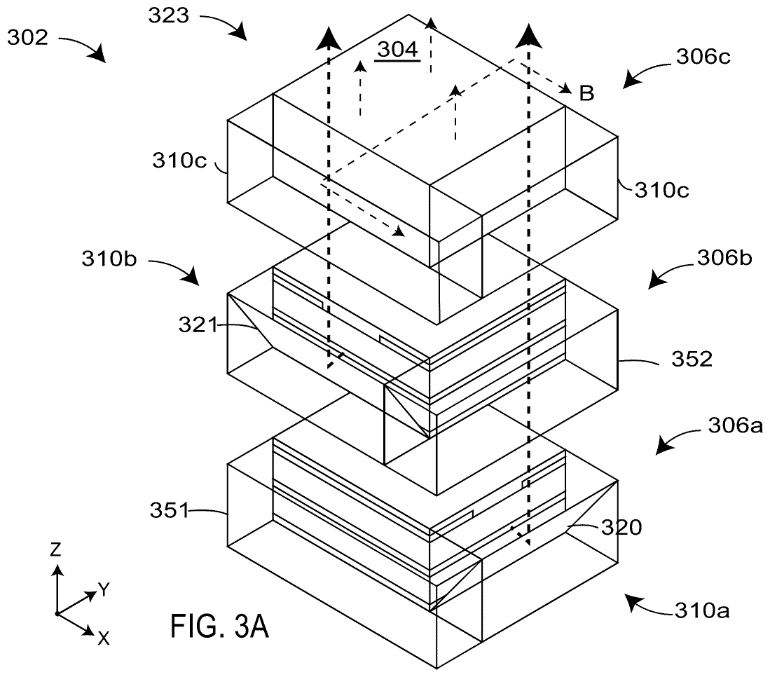

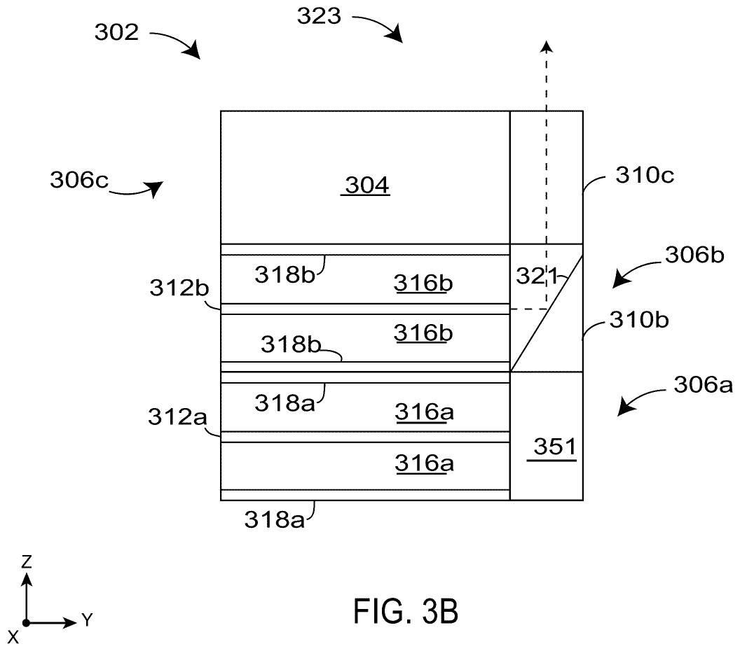

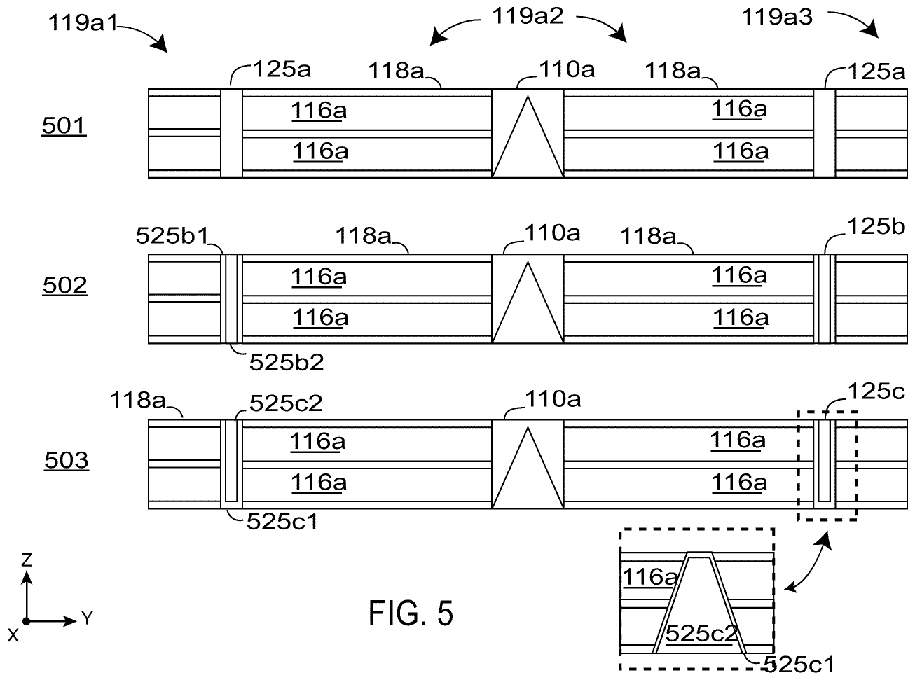

In some embodiments the multilayer stacks 106a-c are stacked or joined together by direct bonding or hybrid bonding. In some other embodiments, the multilayer stacks 106a-c are stacked or joined together by adhesives (e.g. epoxy, flip chip connections, etc.). In some other embodiments, the multilayer stacks 106a-c are stacked or joined together by metal to metal bonding (e.g. thermo-compression bonding). The dotted arrowed lines labeled as “B” represent the cross-section (Z-Y plane) of a pixel 123 further detailed in FIG. 1B without the DTI 125. The pixel 123 may include features such as the DTI 125. Examples of DTI are shown in more detail as various embodiments in FIG. 5. In some embodiments, a length and/or width of the pixel may be about 5 microns, 10 microns, or less than about 5 microns, less than about 10 microns. In some other examples, a length and/or width of the pixel may be less than about 50 microns (e.g. less than about 30 microns, less than about 20 microns, etc.). Although FIG. 1B shows three multilayer stacks (e.g., three substrates comprising edge emitting LEDs), in some embodiments a substrate comprising surface emitting LEDs may be in place of the top multilayer stack and the bottom two multilayer stacks may comprise edge emitting LEDs (e.g., as shown in FIGS. 3A and 3B).

The display 102 comprises an array of 8 by 8 pixels 123 providing a 64 pixel display. Although display 102 shows an embodiment where there are 64 pixels, in other embodiments a display may have any suitable number of pixels (e.g., 1 megapixel (MP, one million pixels), 4MP, 8MP, 50MP, 100MP) in any suitable arrangement (e.g., arranged in an XY grid, etc.). Each pixel 123 comprises three LEDs (e.g., LED 119a, LED 119b, and LED 119c). A pixel may comprise a portion or unit of an active area of a display device, and a plurality of pixels may be used to generate an image on the display device. A pixel 123 is bordered by the DTI 125 which may decrease optical cross talk or ‘light-bleed’ from light generated from neighboring or adjacent pixels. In some embodiments, a DTI for each multilayer stack 106a-c defines each LED 119a, LED 119b, and LED 119c.

Each multilayer stack (e.g., first multilayer stack 106a, second multilayer stack 106b, and third multilayer stack 106c) may comprise one or more edge-emitting LEDs (e.g., edge-emitting LED 119a, edge-emitting LED 119b, edge-emitting LED 119c). A size of an edge-emitting LED may be about be 5-10 microns. In some embodiments, the size or footprint of an edge-emitting LED may be about be less than 5 microns (e.g. <1 microns, <3 microns, etc.). In some embodiments, the size of an edge-emitting LED may be about be less than 50 microns (e.g. <15 microns, <30 microns, etc.) Each edge-emitting LED may comprise a respective active layer (e.g., active layer 112a, active layer 112b, active layer 112c). In the active layer, electron-hole recombination produces photons or light. The active layer may have a thickness of about 100 nm or less than about 100 nm. In some other embodiments, the active layer may have a thickness of about 200 nm or less, about 500 nm or less than about 1 micron. Disposed on top and bottom of each active layer or active region is respective cladding layers or lightguide layers (e.g., lightguide layers 116a, lightguide layers 116b, and lightguide layers 116c). The cladding layers or lightguide layers may sandwich a corresponding central active layer. For example, a central active layer 112a may be between a top and bottom lightguide layer 116a. A central active layer 112b may be between a top and bottom lightguide layer 116b. A central active layer 112c may be between a top and bottom lightguide layer 116c. The central active layer may be made using narrow bandgap material (e.g., InGaAs) bounded by wide bandgap cladding layers (e.g., p+ InGaAsP and n+ InP). The multiple layers may be deposited using epitaxial growth processes (e.g., molecular beam epitaxy (MBE), chemical vapor deposition (CVD), metal organic CVD (MOCVD), plasma enhanced CVD (PECVD), physical vapor deposition (PVD), etc.). The light produced in the active region may be spread into the transparent lightguide regions, effectively reducing the self-absorption of light in the active region. The lightguide layers collect light emitted from the active layer or active region and directs the collected light to the edges of the respective multilayer stack (e.g., through optical principle of total internal reflection (TIR)). The two cladding layers or lightguide layers may also help in confining injected electrons and holes into the middle layer (e.g., central active layer) and improving efficiency.

In some embodiments, as for a color display (e.g., RGB display), each of the three multilayer stacks 106a-c comprise active layers 112a-c that produce light different to one another (e.g., different range of wavelengths). For example, the first multilayer stack 106a of the display 102 may comprise an active layer 112a that produces red light, and some examples of these active layers include aluminum gallium arsenide (AlGaAs), aluminum gallium indium phosphide (AlGaInP), Gallium Arsenide Phosphide (GaAP), Gallium Phosphide (GaP) or any suitable material used to generate red light. The second multilayer stack 106b of the display 102 may comprise an active layer 112b that produces green light, and some examples of these active layers include Aluminium Gallium Indium Phosphide (AlGaInP), Aluminium Gallium Phosphide (AlGaP), indium gallium nitride (InGaN), gallium phosphide (GaP), or any suitable material used generate green light. The third multilayer stack 106c of the display 102 may comprise an active layer 112c that produces blue light, and some examples of these active layers may include indium gallium nitride (InGaN) or any suitable material used to generate blue light. In some embodiments, an active layer may comprise a phosphor.

In some embodiments, the active layer (e.g., active layer 112a, active layer 112b, or active layer 112c) may comprise InGaAs (or GaAs, AlGaAs, etc.) to produce near infrared light (NIR). Edge-emitting LEDs are typically used for long wave optical communication. Various forms of InGaAs, doped with other elements, may emit excitation wavelengths of 1.33 to 1.55 μm. While InGaAs may be the active layer (for NIR applications), it may be bounded by wide bandgap layers (e.g., lightpipe or lightguide layer) such as p+ InGaAsP and n+ InP cladding layers. These two cladding layers (e.g., lightpipe or lightguide layers) help in confining injected electrons and holes into the active layer. The two cladding layers also help emitted photons to travel along the LED (e.g., x and y axis) through TIR and light may be emitted from the edge of the LED (e.g., an edge emitting LED). Edge emitting LEDs may be high brightness LEDs and may radiate less power to the air compared to surface emitting LED due to reabsorption and interfacial recombination.

The first multilayer stack 106a, second multilayer stack 106b, and third multilayer stack 106c each comprise one or more waveguides 110a, waveguides 110b, waveguides 110c, respectively. The waveguides 110a-c of the multilayer stacks 106a-c are centrally disposed in the pixel 123. A size (e.g., width, length, and/or height) of the waveguides 110a-c may be about 500 nm. A width of the waveguide 110a, 110b, and 110c (e.g., along y-axis) may be about 100 nm, 200 nm, 500 nm, 1 micron, 3 micron, or less than about 100 nm, less than about 200 nm, less than about 500 nm, less than about 1 micron less than about 3 micron. In some embodiments, the thickness of the waveguides 110a-c may be less than about 25 microns, or less than about 15 microns, or less than about 10 microns, less than about 5 microns or less than about 3 microns thick. When the waveguides 110a-c of a respective multilayer stack 106a-c is centrally disposed in a pixel 123, an edge-emitting LED 119a-c of the multilayer stack 106a-c may be separated into two portions. Each portion of the edge-emitting LED 119a-c may be optically positioned to emit light towards a respective waveguide 110a-c. The waveguides 110a-c include optical elements to direct light emitted from a respective edge-emitting LED 119a-c towards the surface of the display D, E, F. In some embodiments, each of the two separate portions of LED 119a may be communicatively coupled (e.g., have an electrical connection) to one independent integrated circuit (IC) to operate as a singular pixel 123. For example, each portion of LED 119a may have a contact, connected to a connector and/or via(s), interconnect(s) and bond pad(s), as shown in FIG. 1D, to an IC in a layer below. In some embodiments, when an LED 119a is divided into two separate portions, it may be appreciated that each portion of LED 119a can be communicatively coupled to an independent integrated circuit (IC) (e.g. Readout IC or ROIC, controller chip, etc.) thereby allowing the system of the display to have control over color output. In some embodiments, the bottom most layer 106 as is directly bonded to hybrid bonded to ROIC chip. In some embodiments, bottom most layer 106 as is directly bonded to hybrid bonded to or flip chip attached to a silicon backplane or TFT backplane. In some embodiments, the edge-emitting LEDs comprise optical coatings on the exterior surfaces of each the edge-emitting LEDs to prevent light leakage from the respective active layers. For example, the other side surfaces of the edge-emitting LEDs 119a-c that are not adjacent to a waveguide 110a-c may include a reflective surface to guide light to the waveguide 110a-c. FIG. 5 shows a multilayer stack (e.g., multilayer stack 106a) in which a metal layer, distributed Bragg reflective (DBR) coatings or other type of reflective surface (e.g., DTI 125a, outer portion 525b1 of DTI 125b, outer portion 525cl of DTI 125c) is adjacent to an edge of LEDs 119al and 119a2.

In some embodiments waveguides 110a-c may be referred to as reflecting blocks, reflector blocks, or reflector cubes. Each waveguide (e.g., waveguide 110a, waveguide 110b, and waveguide 110c) may be disposed in an opening (e.g., opening 108a, opening 108b, and opening 108c) of a respective multilayer stack (e.g., multilayer stack 106a, multilayer stack 106b, and multilayer stack 106c). Each waveguide 110a-c may be disposed in the center of each pixel 123. Each waveguide 110a-c may comprise a metalized reflective film, distributed Bragg reflective (DBR) coatings or any other suitable reflecting surface, or reflecting material (e.g., reflector 120, reflector 121, and reflector 122) embedded or disposed in a material layer (e.g., oxide or dielectric material). The material layer may comprise a dielectric material (e.g. oxide material), an oxide fill, glass or other silica derived glasses, or any other suitable optically transparent material. The reflector 120-122 may guide or reflect light emitted from an active layer 112a-c of a corresponding edge-emitting LED 119a-c to the surface of the display 102.

In some embodiments, the reflectors 120-122 may be referred to as mirrors. The reflector (e.g., reflector 120, reflector 121, and reflector 122) may be a semi-transparent element, a beam splitting element or layer, or a partial mirror (e.g., a partially reflecting or partially transmitting mirror).

In some embodiments, the reflective surface or reflector 121 of the second multilayer stack 106b is capable of reflecting light emitted from the active layer 112b of the second multilayer stack 106b and transmitting light emitted from the active layer 112a of the first multilayer stack 106a. The reflective surface or reflector 121 may be a dichroic optical element. In some embodiments, the dichroic optical element may be a dichroic filter or dichroic filter coatings, interference filter, optical bandpass filter, etc. A dichroic filter may transmit light of some wavelengths while reflecting light of other wavelengths. In some embodiments, the dichroic optical element may be a dichroic mirror. A dichroic mirror may reflect light of some wavelengths while transmitting light of other wavelengths. The reflective surface or reflector 121 may be a plurality of thin films (e.g. alternating thin films) of varying materials of varying indices of refraction configured to allow for the transmission of the wavelength band emitted by the active layer 112a of the first multilayer stack 106a while reflecting the wavelength band emitted by the active layer 112b of the second multilayer stack 106b. For example, a dichroic filter may transmit light of the wavelength band emitted by the active layer 112a while reflecting the wavelength band emitted by active layer 112b. As another example, a dichroic mirror may reflect the wavelength band emitted by active layer 112b while transmitting light of the wavelength band emitted by active layer 112a.

In some embodiments, reflective surface or reflector 121 and reflective surface or reflector 122 may be manufactured using dichroic filters. In some embodiments, dichroic filters are multiple layers of dielectric thin films that transmit specific wavelengths of light while reflecting undesired wavelengths at a particular angle of incidence. To manufacture a dichroic filter, thin layers of alternating high and low index refraction materials are applied or formed on a suitable substrate (e.g. glass, oxide, etc.). Light coming into the filter at a specific angle comes in contact with the first index layer and some of the light is reflected and some of the light passes through based on its wavelength which is determined by the index layer. As light travels through these multiple alternating high and low index layers at different speeds, the reflected light either stays in phase (constructive interference) or is reduced by being out of phase (destructive interference) through phase shifts that narrow the final emitted light to a very specific wavelength band. The thickness of the index layers are responsible for the phase shifts and are specifically controlled as well as the number of layers applied to the glass surface to obtain the correct wavelength emitted from the filter. In some embodiments, the reflecting surfaces (e.g., reflectors 120,) and/or reflecting sidewalls of LEDs may be manufactured using metallized mirrors and may be created using a metallization process. The metallization process may involve the deposition and patterning of various metals on an active side of the substrate (e.g., multilayer stack). Metals used in the fabrication of mirrors (e.g., micro mirrors) include aluminum (Al), silver (Ag), gold (Au), chromium (Cr), and indium tin oxide (ITO) or a combination thereof. For example, a thin layer of aluminum may be deposited on a side of a substrate to form the reflector, reflective surface, or micro mirror. An aluminum layer may be deposited using physical vapor deposition (PVD) techniques such as sputtering or evaporation. The deposited aluminum layer may be patterned using photolithography and etching processes to define the reflecting surfaces or mirror structures.

In some embodiments, any of the multilayer stacks comprise an insulation layer 126. The insulation layer 126 may comprise an oxide, nitride, or other suitable material to provide spacing between the metallization layer and the light pipe and active layer. In some embodiments there are no insulating layers 126.

In some embodiments, the display device (e.g., display 102 or any suitable display mentioned in the present disclosure) may comprise vias, bond pads, interconnects, and integrated circuits (IC). In some embodiments, each pixel or sub-pixel may have a corresponding IC for driving the pixel (e.g. ROIC) and each pixel or sub-pixel may have an electrical connection to the corresponding IC. The bond pads, vias, and interconnects may connect and communicatively couple electrical components (e.g., contacts of LEDs) of the multilayer stack to integrated circuits (e.g., in a layer below) of a display device. Examples of vias, interconnects, and bond pads in a layer of a multilayer stack can be found in FIG. 1D and related description.

Each edge-emitting LED may be communicatively coupled to an independent integrated circuit (IC) to control the color output. In some embodiments, the edge-emitting LEDs of one pixel may be communicatively coupled to an independent integrated circuit (IC) to operate as a single pixel 123. In some embodiments, a control device may be coupled to a plurality of pixels. In some embodiments, each multilayer stack 106a-c comprises a respective metallization layer 118a-c disposed on the top and bottom of the multilayer stack or on the outside faces of the respective lightguide layers 116a-c (e.g., light pipe layers). In some embodiments, metallization layer 118a-c may be fabricated using copper, aluminum or transparent metal lines (e.g. transparent conductive oxide (TCO) like ITO).

In some embodiments, the display (e.g., display 102 or any suitable display such as those mentioned in the present disclosure) is an RGB display and the active layer 112a is capable of emitting red light, the active layer 112b is capable of emitting green light, and the active layer 112c is capable of emitting blue light. In some embodiments, the display comprises one color or wavelength. In some embodiments, the display is capable of emitting light of two colors, or a combination thereof. In some embodiments, a display has one or two color emitters, and suitable filters may be applied to form an RGB display. Blue and ultraviolet (UV) light may excite phosphors that emit higher wavelengths, so it may be advantageous to position a blue edge-emitting LED on top of the display (e.g., active layer 112c emits blue light).

Between each the edge-emitting LEDs and respective waveguides may exist a plurality of optical layers. The optical layers may change a polarization of light, an amplitude of light, a direction of light, a dispersion of light, or a phase of light. The display (e.g., display 102 or any suitable display such as those mentioned in the present disclosure) may use any suitable combination of colors or any suitable stacked order of colors.

In some embodiments, the reflector blocks or reflector cubes are superimposed on one another (e.g., overlapping in a top down view) and may comprise reflecting elements to allow the transmission of light therebelow. For example, the openings 108a-c of each the multilayer stacks 106a-c are superimposed, and each respective waveguides 110a-c or reflecting blocks are superimposed. In some embodiments, the openings for each multilayer stack are not superimposed and may comprise reflector blocks or reflector cubes comprising a metal reflector.

In some embodiments each the respective reflector cubes or waveguides 110a-c are directly bonded to the neighboring reflecting block or waveguide 110a-c. In some embodiments each the respective reflector block or waveguides 110a-c are hybrid bonded to the neighboring reflecting block or waveguide 110a-c.

FIG. 1C schematically illustrates an example view of a display 102, according to some embodiments. For example, FIG. 1C shows a top-down view of a part of display 102 highlighted by the dotted line in FIG. 1A labeled “C”. In some embodiments, the display 102 comprising an array of pixels 123. The DTI 125 defines (e.g., optically and electrically separates or provides separation of pixel areas or provides a gap between pixels 123) each pixel of the display 102. In some embodiments, the DTI 125 comprises metal, polySi, reflective coating, oxide, dielectric or a combination thereof. Additional details of DTI configurations can be found in FIG. 5.

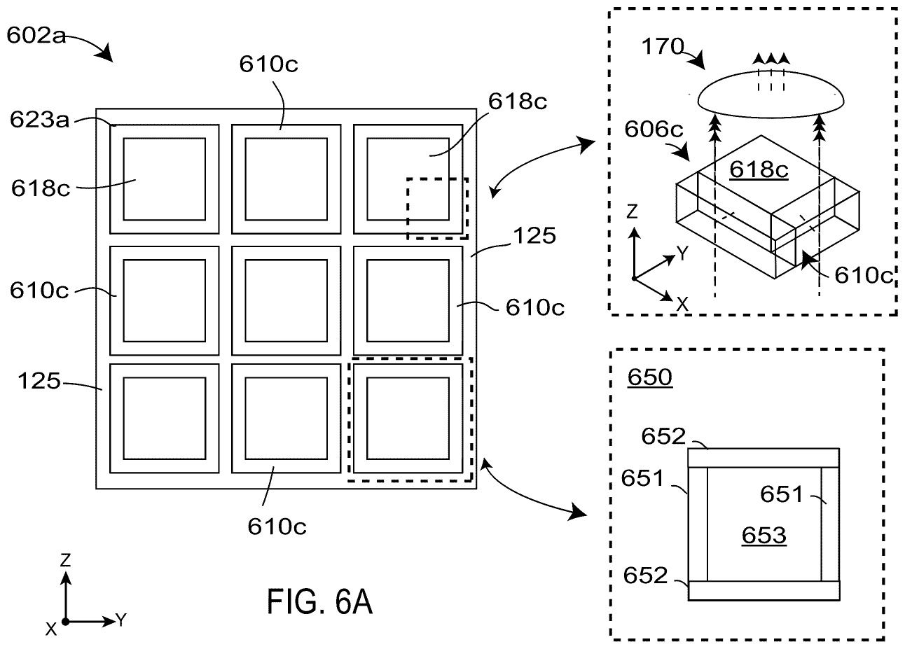

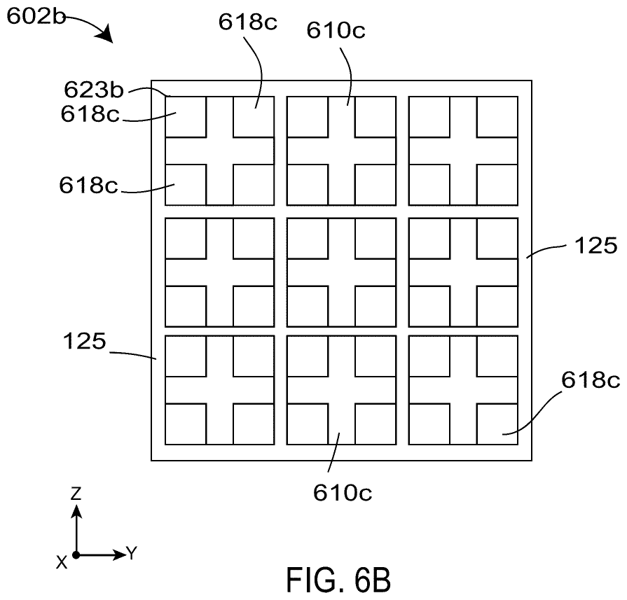

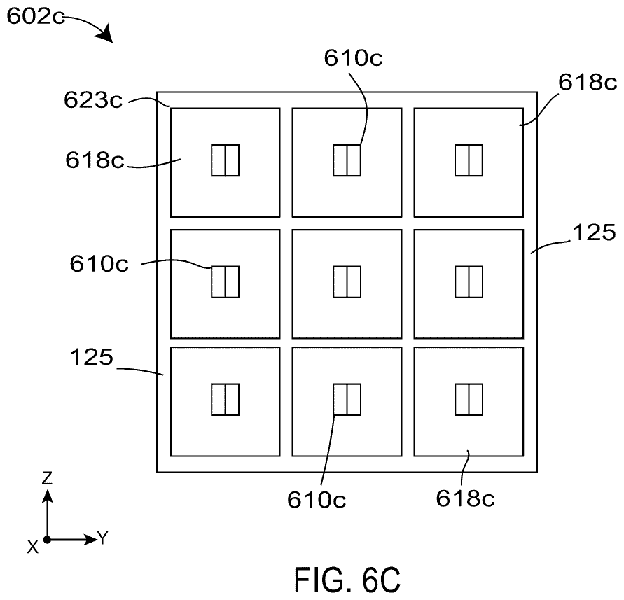

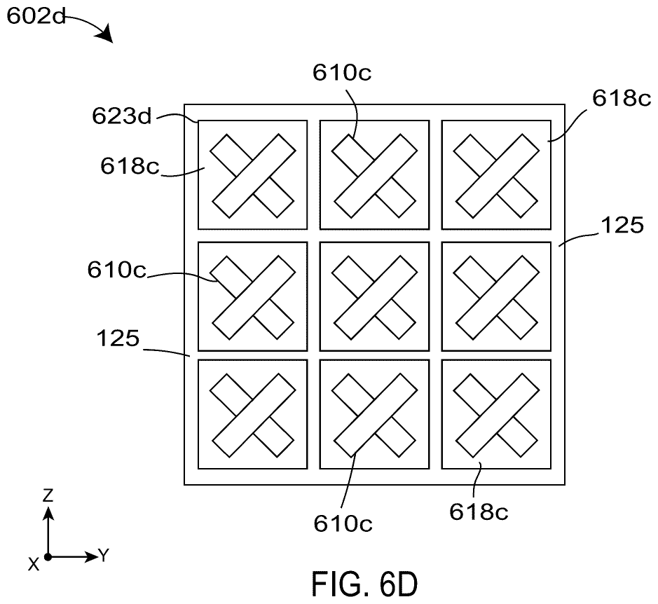

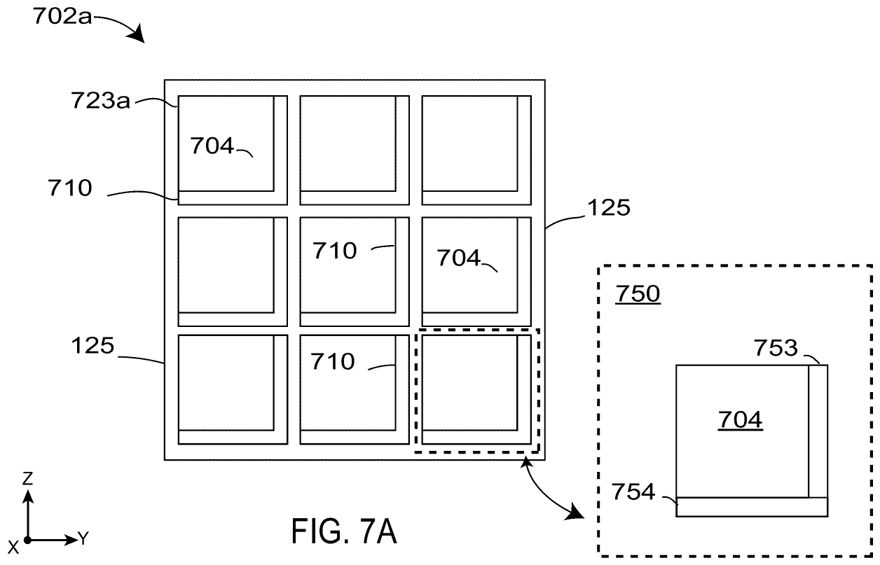

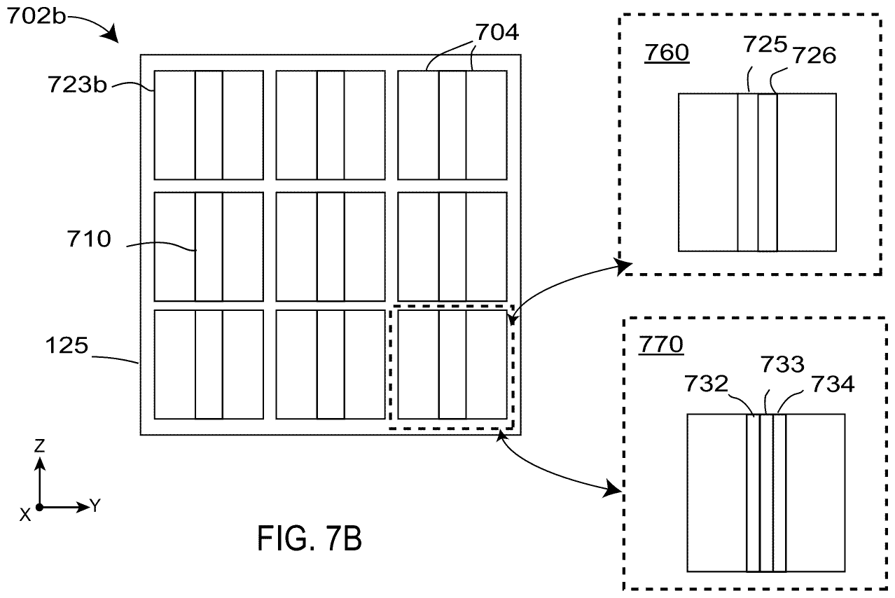

In some embodiments, the edge-emitting LEDs 119a-c comprise centrally located (per pixel) edge emission openings 108a-c and disposed in the openings 108a-c are reflector blocks or waveguides 110a-c. In display device 102, each the respective waveguides 110a-c are superimposed. Although FIG. 1C shows a specific design for the aperture or edge emission openings 108a-c or placement of waveguides 110a-c, various designs may be used for aperture or edge emission openings 108a-c or placement of waveguides 110a-c. Additional details about design for the aperture or edge emission openings 108a-c or placement of waveguides 110a-c including various shapes (cross, line, square, etc.) can be found in FIGS. 6A-6D and 7A-7B.

Although FIGS. 1A-1C shows an embodiment of a display device comprising three stacked multilayer stacks, in other embodiments a display device may comprise any suitable number of stacked multilayer stacks (e.g., two, three, four or more multilayer stacks) and any suitable type of active layers (e.g., use of any suitable active material, emitting light of any suitable color). For example, in some embodiments a display may comprise four multilayer stacks with a multilayer stack comprising LEDs to generate red light, a multilayer stack comprising LEDs to generate blue light, and two multilayer stacks comprising LEDs to generate green light. In some embodiments, the display may comprise a multilayer stack comprising LEDs to generate blue light, a multilayer stack comprising LEDs to generate green light, and a multilayer stack comprising LEDs to generate light with any suitable material (e.g., layer of quantum dots, etc.) that may be disposed on or near to an emissive layer (e.g., layer that generates blue or green light) to convert blue or green emitted light to red light.

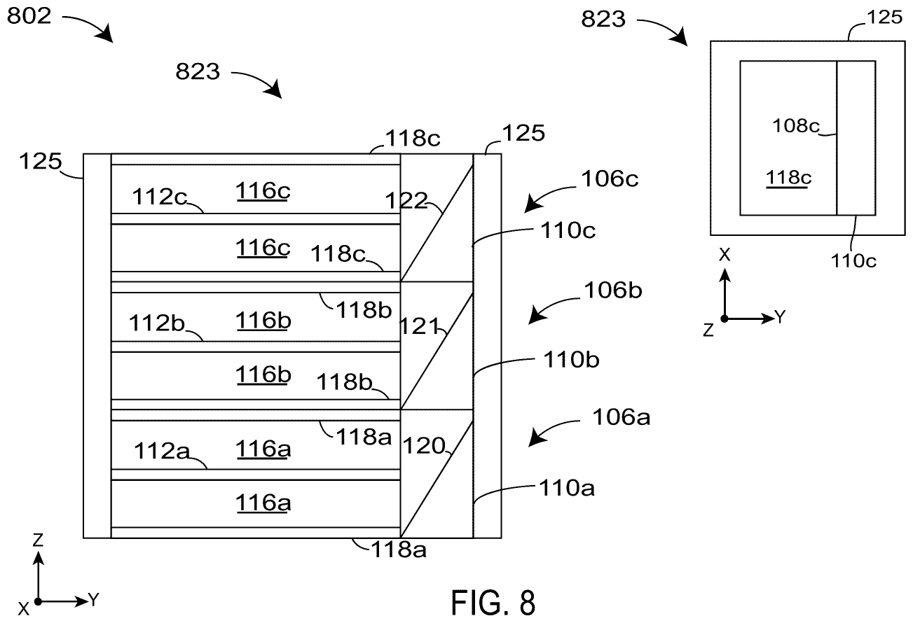

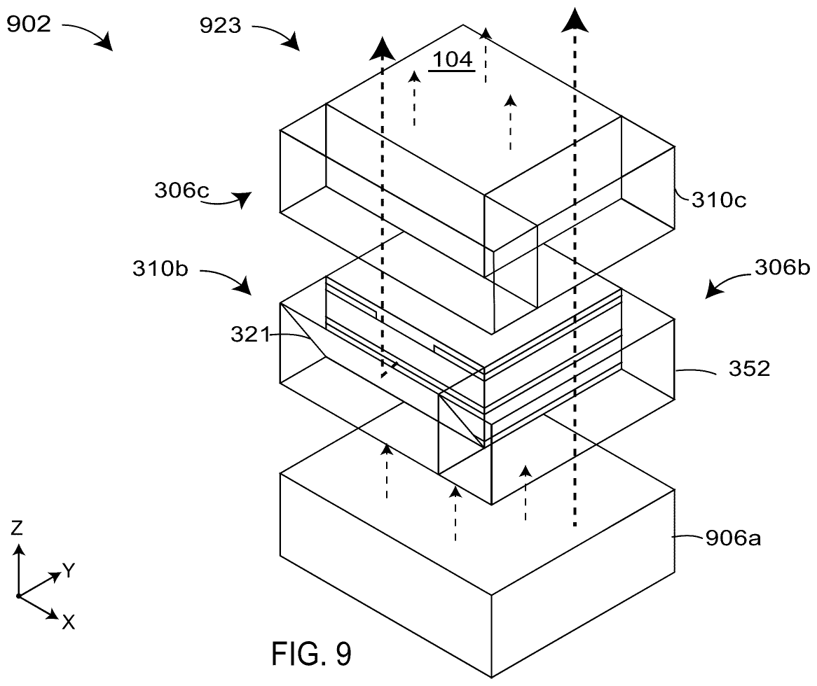

FIG. 1D shows detailed features of a substrate 106 (e.g., wafer, multilayer stack 106a-c, substrate 306c, etc.) comprising an LED 119 and waveguide 110 such as redistribution layers 130 comprising conductive features or bond pads 131, interconnects 132 that include conductive wiring and conductive vias, connectors 136, and vias 137a, 137b. The features shown in FIG. 1D may be applied to any suitable display (e.g., display 102, display 202, display 302, display 402, display 502, display 602, or any display described in embodiments of present disclosure). In some embodiments, LED 119 is a surface-emitting LED (e.g., LED 104 in FIG. 9) with waveguide 110 (e.g., waveguide 310c of FIG. 3A). When LED 119 is an edge-emitting LED, there may be no conductive features or bond pads 131 and interconnects 132 above the LED, ones that are transparent to visible light or wavelength range of interest (e.g., emitted by an underlying surface emitting LED). In some embodiments, LED 119 is an edge-emitting LED (e.g., multilayer stack 106a-c) with waveguide 110 (e.g., waveguides 110a-c) of FIG. 8. When LED 119 is an edge-emitting LED, there may be conductive features or bond pads 131 and interconnects 132 above the LED.

In some embodiments, the substrate 106 of FIG. 1D may include an interconnect layer or redistribution layer 130, such as a redistribution layer (RDL). Contacts or electrodes of an LED 119 may be electrically connected to conductive features (e.g., bond pads 131) via connectors 136 through interconnects 132 in the interconnect layer or redistribution layer 130. The bond pads 131 embedded in a dielectric layer can be hybrid bonded to bond pads of control device (e.g., a processor or controller, ROIC, etc.) embedded, in some embodiments, in the layer below what is shown in FIG. 1D. One or more vias 137a-b may be disposed in the substrate 106 and enable connection through the substrate 106. The bond pads 131, vias 137a-b, connectors 136, and interconnects 132 may comprise any suitable conductive material. For example, a conductive material may include metals such as copper or copper alloys, nickel, aluminum, or alloys, conductive oxide material such as indium tin oxide (ITO).

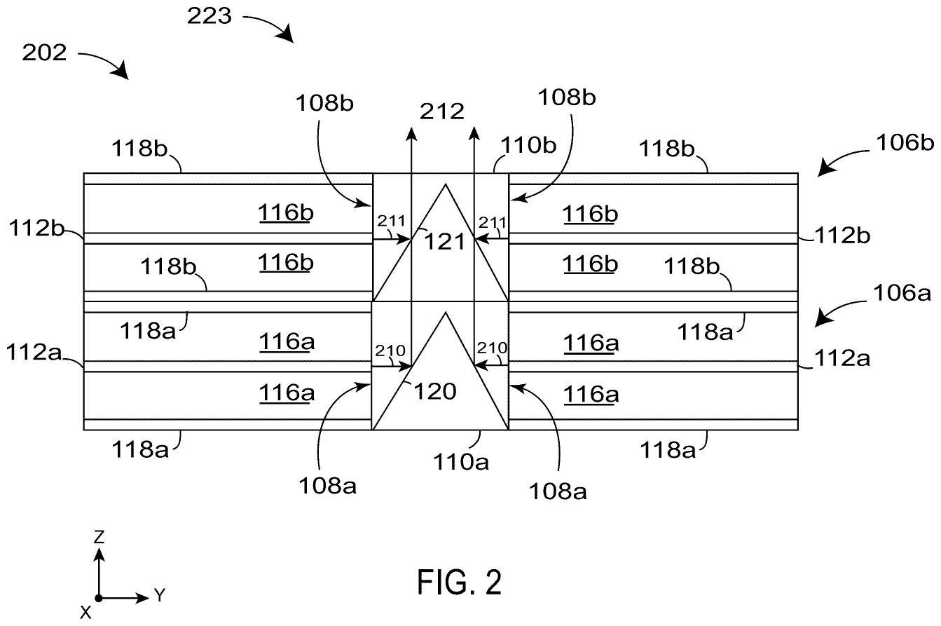

FIG. 2 schematically illustrates an example cross-section of a pixel configuration in a display device, according to some embodiments. FIG. 2 shows a pixel 223 of a display 202 that comprises at least two multilayer stacks (e.g., a first multilayer stack 106a and a second multilayer stack 106b). In some embodiments, the display 202 is similar to or the same as display 102, except the top multilayer stack (e.g., multilayer stack 106c) is removed from the display 102. The display device 202 may have similar features to the display device 102 described above, and therefore the description of similar features is omitted for brevity. The reflector 120 may guide or reflect light emitted from the active layer 112a to the surface of the display 202. The reflector 121 may guide or reflect light emitted from the active layer 112a to the surface of the display 202. The waveguide 110a may be a full reflector (e.g. metallized reflector). The waveguide 110b comprises an oxide or an optically tuned material to allow the transmission of the wavelengths emitted from both the active layer 112a of the first multilayer stack 106a and the active layer 112b of the second multilayer stack 106b. The first multilayer stack 106a may be direct bonded or hybrid bonded to the second multilayer stack 106b. In some other embodiments, the multilayer stacks 106a-c are stacked or joined together by adhesives (e.g. epoxy, flip chip connections, etc.). In some other embodiments, the multilayer stacks 106a-c are stacked or joined together by metal to metal bonding (e.g. thermo-compression bonding).

In some embodiments, the bottom multilayer stack (e.g., multilayer stack 106a) has an active layer 112a capable of emitting blue light (e.g., 380-500 nm). The emitted blue light 210 exits at the opening 108a of the edge-emitting LED, transmits though the material layer of the waveguide 110a, and is reflected by reflector 120 disposed in the waveguide 110a towards the surface of the display 202. The top multilayer stack (e.g., multilayer stack 106b) comprises an active layer 112b capable of emitting green light (e.g., 495-570 nm). The emitted green light 211 exits at the opening 108b, transmits though the material layer of the waveguide 110b, and is reflected by reflector 121 (e.g., a dichroic filter, interference filter, optical bandpass filter, etc.) disposed in the waveguide 110b towards the surface of the display 202. The blue light emitted from the bottom multilayer stack 106a transmits though the dichroic reflector 121 towards the surface of the display. Light 212 exiting a display surface may comprise at least a portion of the emitted blue light 210 and emitted green light 211. In this example, the pixel 223 generates green and blue light and a mixture in between.

FIGS. 3A-3B schematically illustrates example views of a pixel configuration in a display device, according to some embodiments. FIG. 3A shows an example isometric view of a pixel configuration in a display device 302. FIG. 3B shows an example cross section view of a pixel configuration in a display device 302 at dotted lines B in FIG. 3A.

The display device 302 comprises a substrate 306c (e.g., layer, panel, wafer, etc.) disposed on two multilayer stacks (e.g., multilayer stack 306a and multilayer stack 306b). In some embodiments, the multilayer stacks 306a and 306b may correspond to (e.g., may be similar to or the same as) multilayer stacks 106a and 106b, respectively, except that a respective opening and waveguides 310a and 310b in the multilayer stacks 306a and 306b are disposed on one side of a pixel 323 instead of being centrally disposed (e.g., as in the pixel 123). The orientation of the multilayer stacks 306a and 306b are orthogonal to one another (e.g., waveguides 310a and 310b are orthogonal to each other and not overlapping). In some embodiments, waveguides 310a and 310b are parallel, but on the opposite sides of the multilayer stacks 306a and 306b. In some embodiments, the active layer 312a, lightguide layers 316a, metallization layer 318a may correspond to (e.g., is the same or similar to) the active layer 112a, lightguide layers 116a, and metallization layer 118a. The active layer 312b, lightguide layers 316b, metallization layer 318b may correspond to (e.g., be the same as or similar to) the active layer 112b, lightguide layers 116b, and metallization layer 118b. The reflector 320 and reflector 321 may correspond to (e.g., be the same as or similar to) reflector 120 and reflector 121, respectively.

The substrate 306c may comprise a plurality of surface emitting LEDs and light guides or waveguides (shown in FIG. 3A as LED 304 and waveguides 310c). The surface emitting LEDs may comprise a phosphor. The substrate 306c may comprise waveguides 310c (e.g., waveguide block comprising fill material like oxide or glass) disposed in openings of the substrate 306c. The waveguides 310c may be superimposed over top the waveguides 310a and 310b of the multilayer stacks 306a and 306b. The waveguides 310c may comprise optically tuned material that allows for the transmission of light emitted from the first multilayer stack 306a and second multilayer stack 306b. In some embodiments, the waveguides 310a and 310b comprises a dielectric, an oxide, or a combination thereof optically tuned to allow for the transmission of light emitted by the active layer of the first multilayer stack 306a and the transmission of light emitted by the active layer of the second multilayer stack 306b.

It may be appreciated that the first and second multilayer stacks 306a and 306b are not optically superimposed (e.g., comprising light paths that overlap each other) as the first and second multilayer stacks 106a and 106b of FIG. 1B. When multilayer stacks are not optically superimposed, the corresponding waveguides of the multilayer stacks may comprise mirrors such as full reflective mirrors or mirrors tuned to reflect a wavelength range instead of dichroic mirrors, dichroic filters, or dichroic reflectors. For example, light emitted from the active layer of the first multilayer stack 306a and second multilayer stack 306b may exit to respective waveguides 110a and 110b that are positioned orthogonal to one another with non-overlapping light paths, and reflector 320 and reflector 321 may each be a metalized reflector.

In some embodiments, the second multilayer stack 306b comprises a dielectric block 352 that allows for the transmission of light emitted from the first multilayer stack 306a. The first multilayer stack 306a may comprise a block 351. In some embodiments, the block 351 may be a semiconductor material or fill material supporting the area underneath the waveguide 310b of the second multilayer stack 306b. In some embodiments, a side or edge of the LED in of the first multilayer stack 306a (e.g., any suitable side, edge, or portion of a side or edge of the LED that is not at an exit opening or corresponding waveguide) may comprise mirror coatings to reflect light towards the exit opening or waveguides. For example, a side of the first multilayer stack 306a adjacent to block 351 may comprise a mirror coating. In some embodiments, block 351 may be similar to an inner portion 525b2 of DTI 125b, and a metal layer, distributed Bragg reflective (DBR) coatings or other type of reflective surface (e.g., outer portion 525b1 of DTI 125b in FIG. 5) is adjacent to an edge of an LED. In some embodiments, the block 351 may be a portion of the multilayer stack 306a, increasing the surface area of the active layer to increase light output emitted by the active layer of the first multilayer stack 306a.

In some embodiments, the substrate 306c is attached (e.g., directly bonded, hybrid bonded) to the multilayer stack 306b, and the multilayer stack 306b is attached (e.g., directly bonded, hybrid bonded) to the multilayer stack 306a. The waveguide 310c may be directly bonded or hybrid bonded to the waveguide 310b and/or dielectric block 352. The waveguide 310b may be directly bonded or hybrid bonded to the block 351. The dielectric block 352 may be directly bonded or hybrid bonded to the waveguide 310a. In some other embodiments, the multilayer stacks 306a, 306b, and 306c are stacked or joined together by adhesives (e.g. epoxy, flip chip connections, etc.). In some other embodiments, the multilayer stacks 306a-c are stacked or joined together by metal to metal bonding (e.g. thermo-compression bonding).

In some embodiments, a substrate comprising a surface-emitting LED with an active layer and transport layers and/or light guides layers may replace a third multilayer stack 106c of a display device (e.g., display device 102 or display device 802).

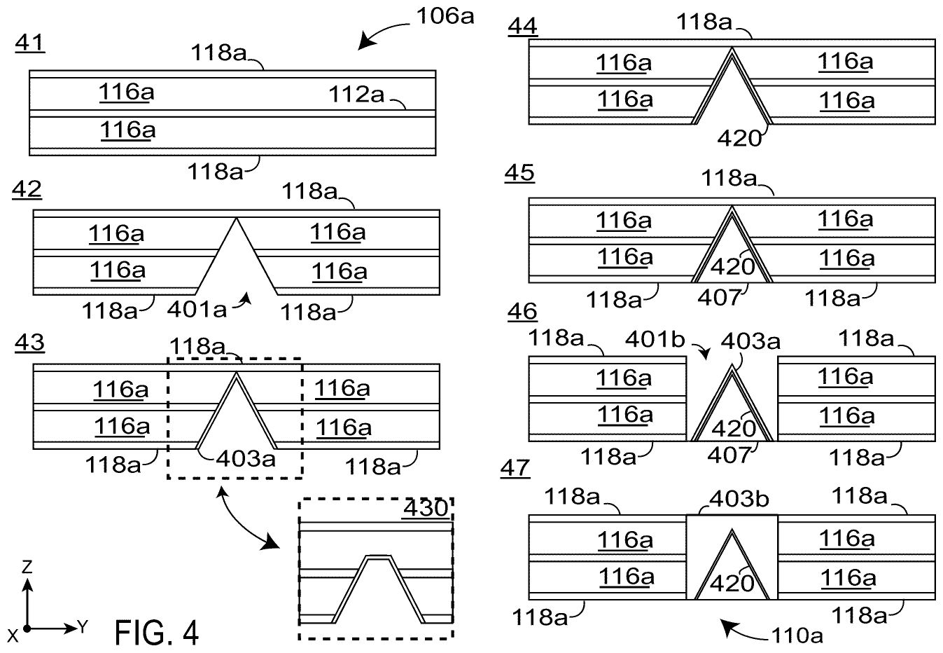

FIG. 4 schematically illustrates aspects of a method of forming a waveguide 110a (e.g., reflector waveguide, reflector block), according to some embodiments. FIG. 4 depicts a cross sectional view of a multilayer stack 106a (e.g., an edge emitting LED structure, a substrate or wafer comprising a plurality of edge emitting LEDs and waveguides). In some embodiments, the multilayer stack 106a may be at the wafer level. At block 41, the method includes providing a multilayer stack 106a. In some embodiments, the multilayer stack 106a may be provided by forming layers (e.g. epitaxially growing layers on a growth substrate) at a wafer level or providing individual wafer levels and stacking them together. In some embodiments, the growth substrate (e.g. sapphire) on which the multilayers of LED structure is grown may be the part of 106a or may be removed (e.g. by laser lift off).

At block 42, the method includes forming openings in a multilayer stack 106a. For example, the method may include etching first openings 401a in multilayer stack 106a. In some embodiments, multilayer stack 106a may be on a carrier substrate, and forming the openings 401a may comprise etching the multilayer stack 106a from a first surface to a second surface opposite the first surface of multilayer stack 106a (e.g., through multilayer stack 106a). The openings may be etched via a wet etch, a dry etch, or any suitable etching technique. The openings may be formed to provide for a particular shape or geometry of the reflector. In some embodiments, the opening may have a shape of a triangle. In some other examples, the opening may have a shape of a trapezoid, ellipsoid, hemisphere, etc.

In some embodiments, the method includes forming openings that are divots. For example, the method may include partially etching the multilayer stack 106a (e.g., openings are not formed from a first surface to a second surface opposite the first surface of the multilayer stack 106a, example shown at inset 430). The opening may be etched through an emissive layer 112a such that a reflector formed in the opening may, at least, overlap a thickness or height of the emissive layer 112a. For example, at least an emission portion (e.g., emissive layer 112a) of the multilayer stack 106a may be etched to have sloped sidewalls, and other portions (e.g., lightguide layer 116a) of the multilayer stack 106a may not be etched or fully etched (e.g., etched through the lightguide layer 116a).

At block 43, the method includes forming a dielectric layer 403a in the first opening 401a in multilayer stack 106a. The dielectric layer 403a may comprise an oxide layer, a nitride layer, a plurality of layers of oxide and/or nitride, or layer of optically tuned material.

At block 44, the method includes forming a reflective layer 420 (e.g., reflector 120) on the dielectric layer 403a in the first opening 401a. In some embodiments, a reflective layer 420 (e.g., reflector 120) is formed directly on the exposed portion of multilayer stack 106a in the first opening 401a without depositing the dielectric layer 403a in the first opening 401a. The reflective layer 420 may comprise a metal layer, a plurality of thin films, a DBR reflector coating, a dichroic, a dichroic filter, a dichroic mirror. In some embodiments, the reflective layer 420 (e.g., reflector 120) covers or overlaps a thickness of the of the emission portion.

At block 45, the method includes forming the dielectric layer 407 on the reflective layer 420 on the dielectric layer 403a in the first opening 401a. The dielectric layer 407 may be a fill layer comprising fill material. A fill material may comprise any suitable fill material such as an organic dielectric, (e.g. resin, polymer, BCB, polyimide, etc.), inorganic dielectric (e.g. silicon oxide, silicon nitride, etc.), silicate material, a transparent material, a non-transparent or opaque material fill, or any suitable material. In some embodiments, a non-transparent or opaque fill material may be used as light is not transmitted through the bottom of the waveguide (e.g., waveguide 110a).

At block 46, the method can include flipping the multilayer stack, attaching to a carrier (from the side of the dielectric layer 407 or fill layer), and removing a portion of the multilayer stack 106a around the dielectric layer 403a. Removing a portion of the multilayer stack 106a may be done by etching. The etching may produce an angle between the angle of the edge-emitting LED opening and the angle of the reflector or reflective layer 420. The angle may be about 45 degrees or less than about 90 degrees. In some embodiments, the shape of the reflector may be a triangular prism, a pyramid, a trapezoid, or any suitable shape.

At block 47, the method includes depositing a material (e.g., dielectric, oxide, optically tuned material) to fill the removed portion of the multilayer stack 106a around the dielectric layer 403a. In some embodiments, optically tuned is defined as low absorption of light within the material. A low absorption may include absorbance rate of less than about 2% of a particular wavelength per unit-distance traveled. In some embodiments, a low absorption may include an absorbance rate of less than about 10%, or less than about 5%, or less than about 3%, or less than about 1% of a particular wavelength per unit-distance traveled. In some embodiments, the dielectric material can be an oxide.

In some embodiments, a waveguide 110a comprises the dielectric layer 407, reflective layer 420, dielectric layer 403a, and dielectric layer 403b. The waveguide 110a may reflect and transmit light emitted from the active layer 112a. In some embodiments, the waveguide 110a comprises an oxide material, a nitride material, a combination thereof, or any suitable dielectric material. In some embodiments, the waveguide 110a comprises multi-layer fill of suitable material.

In some embodiments, the method includes etching portions of the metallization layer 118a of the multilayer stack 106a. In some embodiments, the metallization layer 118a of the multilayer stack 106a may be formed (e.g., deposited or patterned) subsequent to block 47.

In some embodiments, a method of forming a display may comprise, subsequent to block 47, forming one or more DBI layers on surfaces of the multilayer stack 106a. For example, redistribution layers (e.g., redistribution layers 130 as shown in FIG. 1D) may be formed on top and bottom surfaces of multilayer stack 106a. A surface of the multilayer stack 106a (e.g., redistribution layers 130) may be prepared for hybrid bonding using CMP or any suitable techniques such as those described in the present disclosure (e.g., as described in the description of FIGS. 10A-10B). The method of forming the display may include bonding prepared surfaces of multilayer stacks to each other, bonding prepared surfaces of a multilayer stack and a control substrate (e.g., ROIC, substrate comprising control devices, processors, etc.) to each other, and/or bonding prepared surfaces of a multilayer stack (e.g., substrate of edge-emitting LEDs and waveguides) and a substrate comprising surface emitting LEDs and waveguides to each other.

In some embodiments, the waveguide 110a forms two separate LEDs. For example, instead of two portions of LED 119a with a waveguide 110a disposed centrally in the LED 119a as shown in FIGS. 1A-1C, a pixel may comprise one half of the LED 119a and one half of the waveguide 110a. A first pixel may comprise a left portion of the LED 119a and a left portion of the waveguide 110a, and second pixel may comprise a right portion of LED 119a and a right portion of waveguide 110a. (e.g., pixel 123 of FIGS. 1A-1C may be split in half to form two pixels).

In some embodiments, the multilayer stack 106a may be etched or partially etched to form a larger separation between the pixels. For example, a spacing between adjacent LEDs 119a may be increased to have a larger separation between the pixel (e.g. for dicing). In some embodiments, the multilayer stack 106a may be diced to separate one or more LEDs and corresponding waveguides from other LEDs and corresponding waveguides (e.g., for singulation or for a suitable size or arrangement of pixels in an XY grid, etc.).

FIG. 5 schematically illustrates aspects of DTIs, according to some embodiments. In example configurations 501, 502, and 503, three LEDs 119a1, 119a2, and 119a3 (or pixels of display) defined by DTIs 125a, 125b, and 125c. The DTIs 125a, 125b, and 125c may comprise a reflector. In example configuration 501, the DTI 125a may comprise a material (e.g., fill material) comprising a metal, polysilicon (polySi), semiconductor coatings, reflector coating, DBR coatings, or some combination thereof. In example configuration 502, DTI 125b may comprise an outer portion 525b1 and an inner portion 525b2. The outer portion 525b1 may comprise a material comprising a metal, polysilicon (polySi), semiconductor coatings, reflector coating, or some combination thereof. The inner portion 525b2 may comprise a dielectric material (e.g. an oxide). In some embodiments, the outer portion of DTI (e.g., outer portion 525b1 of DTI 125b, or outer portion 525cl of DTI 125c) may be a reflector (e.g., at a sidewall of an edge-emitting LED) that reflects light from an edge-emitting LED 119a2 internally (e.g., internal to the edge-emitting LED 119a2) towards a reflector in a waveguide (e.g., waveguide 110a) to direct or reflect light towards a viewing surface of the display to exit the display. In some embodiments, the outer portion of the DTI (e.g., outer portion 525b1 of DTI 125b, or outer portion 525cl of DTI 125c, or the portion shown directly adjacent to or facing LED 119a2) is reflecting light internally for LED 119a2 as well as LED 119al (e.g., outer portion 525b1 of DTI 125b, or outer portion 525cl of DTI 125c, or the portion shown directly adjacent to or facing LED 119a1). In example configuration 503, the DTI 125c is similar to DTI 125b except an outer portion 525cl is on a bottom outer portion of the DTI 125c. For example, outer portion 525cl corresponds to outer portion 525b2, and inner portion 525c2 corresponds to inner portion 525 b1. An inset shows a variation of DTI 125c with a different shape. For example, an opening in a multilayer stack may be etched in a particular shape for the DTI. In some embodiments, the multilayer stack may be etched to form a particular shape of the DTI 125c.

In some embodiments, the DTIs 125a, 125b, and 125c are spaced apart by a distance corresponding to a single pixel pitch. In some embodiments, the distance may correspond to any suitable number of pixel pitch (e.g., one, two, three or more times the pixel pitch).

FIGS. 6A-6D schematically illustrate example top views of a display device, according to some embodiments. For example, FIGS. 6A-6D may illustrate variations of a pixel configuration of a display 102 of FIG. 1C. The display devices (e.g., display device 602a, display device 602b, display device 602c, and display device 602d) may have similar features to the display device 102 described above, and therefore the description of similar features is omitted for brevity. In some embodiments, pixels 623a-d (e.g., pixel 623a, pixel 623b, pixel 623c, pixel 623d), multilayer stack 606c, waveguides 610c, and metallization layer 618c of display devices 602a-d correspond to pixel 123, multilayer stack 106c, waveguides 110c, and metallization layers 118c of display device 102.

In FIG. 6A, the display 602a shows an array of 3×3 pixels 623a. The pixels 623a are separated by a DTI 125 and comprise openings on all 4 sides of the square shaped pixel 623a. Disposed in the openings are waveguides 610c similar to that described in FIG. 1B, the difference being that the openings and waveguides 610c are disposed on the exterior of the edge-emitting LED, and therefore comprise 4 emissive faces (or sides) instead of a singular central face (e.g., four emissive portions on each edge of the pixel 623a instead of a central emissive portion of pixel 123). Although one waveguide surface (e.g., waveguide 610c corresponding to waveguide 110c) is shown it is appreciated that the waveguide of the second layer (e.g. waveguide corresponding to waveguide 110b of multilayer stack 106b) and waveguide of the first layer (e.g., waveguide corresponding to waveguide 110a of multilayer stack 106a) are superimposed over one another as in the illustrative example of FIG. 1B. In some embodiments, each pixel 623a or any suitable pixel, such as those mentioned in embodiments of this disclosure has a separate intra-pixel separation. In some embodiments, each pixel 623a or any suitable pixel, such as those mentioned in embodiments of this disclosure has a separate optical element (e.g., lens) disposed over the pixel for light manipulation (e.g., collimation). In some embodiments the optical element is a square lens 170, or a diffuser. In some other embodiments the optical element is an optical filter or a quantum dot layer.

In some embodiments, a substrate with surface-emitting LEDs 104 may be used in place of a multilayer stack comprising edge-emitting LEDs and waveguides 610c. For example, a surface-emitting LED 104 may be in place of the metallization layer 618c in FIG. 6A. The inset 650 shows an example of a configuration of a variation on pixel 623a. The inset 650 may show details of different layers superimposed on each other or details of underlying layers of the multilayer stacks (e.g., corresponding to multilayer stack 106a or 106b). In some embodiments, block 653 may correspond to a surface-emitting LED 104. In some embodiments, a bottom multilayer stack corresponding to multilayer stack 106a may have reflectors at block 651 and waveguides at block 652. In some embodiments, an intermediate multilayer stack corresponding to multilayer stack 106b may have reflectors at block 652 and waveguides at block 651. The reflectors (e.g., mirror on sides of edge-emitted LED) may confine emitted light to an LED of a multilayer stack and the waveguides (e.g., reflector block with angled mirror) may enable emit ted light of the LED to exit the LED or multilayer stack.

FIGS. 6B-6D show other example variations of pixel configurations. In the example of FIG. 6B the waveguide 610c forms a cross shape on the pixel structure (e.g., pixel 623b). In the example of FIG. 6C the waveguide 610c forms a small square centrally in the pixel structure (e.g., pixel 623c), a line in the square indicating the reflector. In some embodiments, each of the multilayer stack has a small waveguide 610c, which is offset from the similar waveguide within multilayer stack above or below it. In some embodiments, the waveguide 610c may be circular, rectangular, elliptical or any other regular or irregular shapes. In the example of FIG. 6D the waveguide 110c forms an “X” shape centrally in the pixel structure (e.g., pixel 623d) where one part of a line of the “X” is in a different layer than the other. In some embodiments, the waveguides 610c are formed in a same layer. In some embodiments, the waveguide 610c and corresponding reflector may be any suitable shape or suitable size. In some embodiments, a substrate with surface-emitting LEDs may be used in place of a multilayer stack comprising edge-emitting LEDs and waveguides 610c of the display devices 602a-d.

FIGS. 7A-7B schematically illustrate example top views of a display device, according to some embodiments. For example, FIGS. 7A-7B may illustrate variations of a pixel configuration of a display 302 of FIGS. 3A-3B, in which a substrate 306c of surface-emitting LEDs (e.g., LED 304) is on top of multilayer stacks 306a and 306b. The display devices 702a-b may have similar features to the display device 302 described above, and therefore the description of similar features is omitted for brevity. In some embodiments, pixels 723a-b, LED 704, and waveguide 710 of display devices 702a-b correspond to pixel 323, LED 304 (e.g., surface emitting LED), and waveguide 310c of display device 302. In some embodiments, the LED 704 is capable of emitting light different to that of the active layers therebelow. In some embodiments, LED 704 may be capable of emitting light similar to that of the active layers therebelow.

FIG. 7A illustrates a 3×3 array of pixels 723a of a display 702a. The inset 750 shows example detail of a pixel 723a. For example block 753 may correspond to a waveguide in an intermediate multilayer stack corresponding to waveguide 310b and multilayer stack 306b, and block 754 may correspond to a waveguide in a bottom multilayer stack corresponding to waveguide 310a and multilayer stack 306a.

FIG. 7B illustrates a 3×3 array of pixels 723b of a display 702b. The inset 760 shows example detail of a pixel 723b. For example, block 725 may correspond to a waveguide in an intermediate multilayer stack corresponding to waveguide 310b and multilayer stack 306b, and block 726 may correspond to a waveguide in a bottom multilayer stack corresponding to waveguide 310a and multilayer stack 306a.

The inset 770 shows example detail of a variation to example pixel 723b of display device 702b. The inset 770 may show details of different layers superimposed on each other. In some embodiments, a multilayer stack with edge-emitting LEDs and waveguides may be used in place of a substrate comprising surface-emitting LEDs 704. For example, block 732 may correspond to a waveguide in a top multilayer stack corresponding to waveguide 110c and multilayer stack 106c. Block 733 may correspond to a waveguide in an intermediate multilayer stack corresponding to waveguide 110b and multilayer stack 106b, and block 734 may correspond to a waveguide in a bottom multilayer stack corresponding to waveguide 110a and multilayer stack 106a.

FIG. 8 schematically illustrates a cross-section of a pixel configuration in display device, according to some embodiments. In some embodiments, the example display device 802 is similar to or the same as display device 202 of FIG. 2 except display device 802 includes a third multilayer stack 106c and DTI 125 on each side of pixel 823. The display device 802 may have similar features to the display device 202 described above, and therefore the description of similar features is omitted for brevity. Inset included with FIG. 8 shows a top-down view of a pixel 823 to exemplify how the top of waveguide 110c (e.g., the emissive face of the pixel) may be viewed.

FIG. 9 schematically illustrates an example view of pixel configuration in a display device, according to some embodiments. In some embodiments, the example display device 902 is similar to or the same as display device 302 of FIGS. 3A-3B except a substrate 906a (e.g., comprising surface emitting LEDs) is used in place of multilayer stack 306a of display device 302. The bottom substrate 906a may comprise a plurality of surface emitting LEDs. In some embodiments, a surface emitting LED may comprise a phosphor layer.

In some embodiments, a reflector or mirror may be a dichroic mirror or dichroic filter. For example, a reflector may transmit light of wavelengths in a first range of wavelengths and reflect light of wavelengths in another range of wavelengths (e.g., red, green, blue, red/green, green/blue, red/blue light). In some embodiments, the reflector or mirror may be a complete mirror or a full mirror.

In some embodiments, the display device may further comprise a brightness enhancement film (BEF). The BEF may manage angular light output from the display device. The BEF may use a prismatic structure to focus light towards on-axis viewers of the display. The BEF may refracts light within the viewing cone (up to 35° off the perpendicular) toward the viewer. Light outside this angle is reflected back and recycled until it exits at the proper angle. The BEF may minimize or reduce coupling to adjacent surfaces. The BEF can be used alone or two BEFs can be crossed, e.g., at 90 degrees to each other. A single sheet or BEF may provide up to 60% increase in brightness and two sheets crossed at 90° can provide up to 120% brightness increase.

In some embodiments, a display device may comprise monochromatic stacks of wafers using edge-emitted LEDs with reflectors from a same edge (e.g., of the pixel). In some embodiments, each multilayer stack 106a-c is an LED wafer of one particular color. For example, a wafer of red edge-emitting LEDs (e.g., multilayer stack 106c of FIG. 8) may be stacked on or attached to a wafer of green edge-emitting LEDs (e.g., multilayer stack 106b of FIG. 8), and a wafer of green edge-emitting LEDs may be stacked on or attached to a wafer of blue edge-emitting LEDs (e.g., multilayer stack 106a of FIG. 8). Each wafer may comprise reflecting blocks or cubes (e.g., waveguides 110a, 110b, 110c of FIG. 8) with appropriate dichroic coatings next to the emission layers of the red edge-emitting LEDs, green edge-emitting LEDs, and blue edge-emitting LEDs. The reflecting block or cube (e.g., waveguide 110c) next to red edge-emitting LED may comprise a dichroic film (e.g., reflector 122) tuned to reflect red light and transmit green and blue light. The reflecting block or cube (e.g., waveguide 110b) next to green edge-emitting LED may comprise a dichroic film (e.g., reflector 121). The dichroic film (e.g., reflector 121) next to the green edge-emitting LED may comprise a dichroic film tuned to reflect green light and transmit blue light. In some embodiments, the reflecting block or cube (e.g., waveguide 110a) next to the blue edge-emitting LED may not comprise a dichroic film and may be a full mirror (e.g., reflector 120).

In some embodiments, a display device (e.g., display device 302 of FIGS. 3A-3B) may comprise a wafer with a surface emitting LED (e.g., red LED), and wafers with edge-emitting LEDs (e.g., green and blue edge-emitting LEDs). For example, a top substrate (e.g., substrate 306c) may comprise surface-emitting red LEDs, and intermediate substrate (e.g., multilayer stack 306b) may comprise a wafer of green edge-emitting LEDs, and a bottom substrate (e.g., multilayer stack 306a) may comprise a wafer of blue edge-emitting LEDs. Reflector blocks or cubes may be next to emission layers of edge-emitting LEDs. For example, there may be no reflector block or cube next to the red surface-emitting LED. A reflector block or cube (e.g., waveguide 310b) next to a green edge-emitting LED may comprise a dichroic film (e.g., reflector 321) tuned to reflect green light and transmit blue light. A reflector block or cube (e.g., 310a) next to a blue edge-emitting LED may not comprise a dichroic film and may comprise a full mirror (e.g., reflector 320). In some embodiments, the reflector blocks may be from a same edge (e.g., of the pixel). In some embodiments, the reflector blocks may be from perpendicular edges (e.g., of the pixel). For example, a reflector block next to green edge-emitting LED may be from a first edge of a pixel, and a reflector block next to a blue edge-emitting LED may be from a second edge of the pixel, the second edge may be perpendicular to the first edge of the pixel.

In some embodiments, a mirror may be a full mirror, a dichroic mirror, or a dichroic filter. In some embodiments, where light emission of LEDs overlaps in a vertical dimension, a dichroic mirror or a dichroic filter may be used. In some embodiments, where there is no overlap of different colored lights, a full mirror may be used.

In some embodiments, reflectors may be near intra-pixel separation portion of a substrate comprising edge-emitting LEDs. For example, a reflector block with reflectors at different angles may separate a first LED and a second LED of a substrate comprising edge-emitting LEDs. In some embodiments, a reflective layer comprising the reflector may be formed to cover only at least an emission portion with sloped sidewalls (e.g., from a bottom portion of the edge-emitting LED to an emission portion of the edge-emitting LED and not a top portion of the edge-emitting LED). In some embodiments, there may be a larger separation for dicing. For example, a top portion of two reflectors corresponding to adjacent edge-emitting LEDs may not meet to form a point in the substrate (e.g., triangular shape), and may have a flat top (e.g., form a trapezoidal shape).

In some embodiments, a lens may be on each pixel. Each pixel may comprise light emitted from edges of each edge-emitting LED in a top view. A square shaped or circular shaped lens may be on each pixel. In some embodiments, lens on each pixel may be a Fresnel lens. In some embodiments, a display device may comprise three substrates comprising edge-emitting LEDs of three colors. All three colors of edge-emitting LEDs may be superimposed from a top view, and all three colors may overlap. Each pixel may have a separate intra-pixel separation. Each pixel may have a separate lens for light collimation.

In some embodiments, a display device may comprise reflectors in a central or center portion of an edge-emitting LED (e.g., corresponding to one pixel of a display device). The reflectors may be positioned in a center portion of a pixel, and distribute light emitted from edge-emitting LEDs surrounding the reflectors (e.g., right and left to the reflectors) to a center portion of the pixel.

In some embodiments, each pixel may have a separate intra-pixel separation. In some embodiments, intra-pixel separation may be coated with a reflective coating to reflect light inwards towards an extraction area (e.g., of a pixel). Each pixel may have a separate lens for light collimation. A reflective coating on sidewalls may be used for intra-pixel separation.

In some embodiments, reflectors at an edge of an LED may be used for central edge emission (e.g., extraction of emitted light from an edge-emitting LED in a central portion of a pixel). Reflectors (e.g., comprising metal, polySi, reflector coatings, etc.) may be at one end of the LED wave guide. In some embodiments, reflectors may be at opposite edges of a pixel area. An oxide or a dielectric material may be in an interior portion of the reflector.

It is contemplated that any combination of the methods described above may be used to form a display whether or not expressly recited herein.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1008a and/or 1008b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 10A and 10B schematically illustrate cross-sectional side views of first and second elements 1002, 1004 prior to and after, respectively, a process for forming a directly bonded structure, and more particularly a hybrid bonded structure, according to some embodiments. In FIG. 10B, a bonded structure 1000 comprises the first and second elements 1002 and 1004 that are directly bonded to one another at a bond interface 1018 without an intervening adhesive. Conductive features 1006a of a first element 1002 may be electrically connected to corresponding conductive features 1006b of a second element 1004. In the illustrated hybrid bonded structure 1000, the conductive features 1006a are directly bonded to the corresponding conductive features 1006b without intervening solder or conductive adhesive.

The conductive features 1006a and 1006b of the illustrated embodiment are embedded in, and can be considered part of, a first bonding layer 1008a of the first element 1002 and a second bonding layer 1008b of the second element 1004, respectively. Field regions of the bonding layers 1008a, 1008b extend between and partially or fully surround the conductive features 1006a, 1006b. The bonding layers 1008a, 1008b can comprise layers of non-conductive materials suitable for direct bonding, as described above, and the field regions are directly bonded to one another without an adhesive. The non-conductive bonding layers 1008a, 1008b can be disposed on respective front sides 1014a, 1014b of base substrate portions 1010a, 1010b.

The first and second elements 1002, 1004 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1002, 1004, and back-end-of-line (BEOL) interconnect layers over such semiconductor portions. The bonding layers 1008a, 1008b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1010a, 1010b, and can electrically communicate with at least some of the conductive features 1006a, 1006b. Active devices and/or circuitry can be disposed at or near the front sides 1014a, 1014b of the base substrate portions 1010a, 1010b, and/or at or near opposite backsides 1016a, 1016b of the base substrate portions 1010a, 1010b. In other embodiments, the base substrate portions 1010a, 1010b may not include active circuitry, but may instead comprise dummy substrates, passive interposers, passive optical elements (e.g., glass substrates, gratings, lenses), etc. The bonding layers 1008a, 1008b are shown as being provided on the front sides of the elements, but similar bonding layers can be additionally or alternatively provided on the back sides of the elements.

In some embodiments, the base substrate portions 1010a, 1010b can have significantly different coefficients of thermal expansion (CTEs), and bonding elements that include such different based substrate portions can form a heterogenous bonded structure. The CTE difference between the base substrate portions 1010a and 1010b, and particularly between bulk semiconductor (typically single crystal) portions of the base substrate portions 1010a, 1010b, can be greater than 5 ppm/° C. or greater than 10 ppm/° C. For example, the CTE difference between the base substrate portions 1010a and 1010b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 1010a, 1010b can comprise optoelectronic single crystal materials, including perovskite materials, that are useful for optical piezoelectric or pyroelectric applications, and the other of the base substrate portions 1010a, 1010b comprises a more conventional substrate material. For example, one of the base substrate portions 1010a, 1010b comprises lithium tantalate (LiTaO₃) or lithium niobate (LiNbO₃), and the other one of the base substrate portions 1010a, 1010b comprises silicon (Si), quartz, fused silica glass, sapphire, or a glass. In other embodiments, one of the base substrate portions 1010a, 1010b comprises a III-V single semiconductor material, such as gallium arsenide (GaAs) or gallium nitride (GaN), and the other one of the base substrate portions 1010a, 1010b can comprise a non-III-V semiconductor material, such as silicon (Si), or can comprise other materials with similar CTE, such as quartz, fused silica glass, sapphire, or a glass. In still other embodiments, one of the base substrate portions 1010a, 1010b comprises a semiconductor material and the other of the base substrate portions 1010a, 1010b comprises a packaging material, such as a glass, organic or ceramic substrate.

In some arrangements, the first element 1002 can comprise a singulated element, such as a singulated integrated device die. In other arrangements, the first element 1002 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1004 can comprise a singulated element, such as a singulated integrated device die. In other arrangements, the second element 1004 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1002, 1004 are shown, any suitable number of elements can be stacked in the bonded structure 1000. For example, a third element (not shown) can be stacked on the second element 1004, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1002. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1008a, 1008b, the bonding layers 1008a, 1008b can be prepared for direct bonding. Non-conductive bonding surfaces 1012a, 1012b at the upper or exterior surfaces of the bonding layers 1008a, 1008b can be prepared for direct bonding by polishing, for example, by chemical mechanical polishing (CMP). The roughness of the polished bonding surfaces 1012a, 1012b can be less than 30 Å rms. For example, the roughness of the bonding surfaces 1012a and 1012b can be in a range of about 0.1 Å rms to 15 Å rms, 0.5 Å rms to 10 Å rms, or 1 Å rms to 5 Å rms. Polishing can also be tuned to leave the conductive features 1006a, 1006b recessed relative to the field regions of the bonding layers 1008a, 1008b.

Preparation for direct bonding can also include cleaning and exposing one or both of the bonding surfaces 1012a, 1012b to a plasma and/or etchants to activate at least one of the surfaces 1012a, 1012b. In some embodiments, one or both of the surfaces 1012a, 1012b can be terminated with a species after activation or during activation (e.g., during the plasma and/or etch processes). Without being limited by theory, in some embodiments, the activation process can be performed to break chemical bonds at the bonding surface(s) 1012a, 1012b, and the termination process can provide additional chemical species at the bonding surface(s) 1012a, 1012b that alters the chemical bond and/or improves the bonding energy during direct bonding. In some embodiments, the activation and termination are provided in the same step, e.g., a plasma to activate and terminate the surface(s) 1012a, 1012b. In other embodiments, one or both of the bonding surfaces 1012a, 1012b can be terminated in a separate treatment to provide the additional species for direct bonding. In various embodiments, the terminating species can comprise nitrogen. For example, in some embodiments, the bonding surface(s) 1012a, 1012b can be exposed to a nitrogen-containing plasma. Other terminating species can be suitable for improving bonding energy, depending upon the materials of the bonding surfaces 1012a, 1012b. Further, in some embodiments, the bonding surface(s) 1012a, 1012b can be exposed to fluorine. For example, there may be one or multiple fluorine concentration peaks at or near a bond interface 1018 between the first and second elements 1002, 1004. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1000, the bond interface 1018 between two non-conductive materials (e.g., the bonding layers 1008a, 1008b) can comprise a very smooth interface with higher nitrogen (or other terminating species) content and/or fluorine concentration peaks at the bond interface 1018. In some embodiments, the nitrogen and/or fluorine concentration peaks may be detected using various types of inspection techniques, such as SIMS techniques. The polished bonding surfaces 1012a and 1012b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1008a and 1008b can be directly bonded to one another without an adhesive. In some embodiments, the elements 1002, 1004 are brought together at room temperature, without the need for application of a voltage, and without the need for application of external pressure or force beyond that used to initiate contact between the two elements 1002, 1004. Contact alone can cause direct bonding between the non-conductive surfaces of the bonding layers 1008a, 1008b (e.g., covalent dielectric bonding). Subsequent annealing of the bonded structure 1000 can cause the conductive features 1006a, 1006b to directly bond.

In some embodiments, prior to direct bonding, the conductive features 1006a, 1006b are recessed relative to the surrounding field regions, such that a total gap between opposing contacts after dielectric bonding and prior to anneal is less than 15 nm, or less than 10 nm. Because the recess depths for the conductive features 1006a and 1006b can vary across each element, due to process variation, the noted gap can represent a maximum or an average gap between corresponding conductive features 1006a, 1006b of two joined elements (prior to anneal). Upon annealing, the conductive features 1006a and 1006b can expand and contact one another to form a metal-to-metal direct bond.

During annealing, the conductive features 1006a, 1006b (e.g., metallic material) can expand while the direct bonds between surrounding non-conductive materials of the bonding layers 1008a, 1008b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1006a, 1006b can comprise discrete pads, contacts, electrodes, or traces at least partially embedded in the non-conductive field regions of the bonding layers 1008a, 1008b. In some embodiments, the conductive features 1006a, 1006b can comprise exposed contact surfaces of TSVs (e.g., through silicon vias).

As noted above, in some embodiments, in the elements 1002, 1004 of FIG. 10A prior to direct bonding, portions of the respective conductive features 1006a and 1006b can be recessed below the non-conductive bonding surfaces 1012a and 1012b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1006a, 1006b or to average depths of the recesses relative to local non-conductive field regions. Even for an individual conductive feature 1006a, 1006b, the vertical recess can vary across the feature, and so can be measured at or near the lateral middle or center of the cavity in which a given conductive feature 1006a, 1006b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 1006a, 1006b across the direct bond interface 1018 (e.g., small or fine pitches for regular arrays).

In some embodiments, a pitch p of the conductive features 1006a, 1006b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1006a and 1006b to one of the lateral dimensions (e.g., a diameter) of the bonding pad is less than is less than 20, or less than 10, or less than 5, or less than 3 and sometimes desirably less than 2. In various embodiments, the conductive features 1006a and 1006b and/or traces can comprise copper or copper alloys, although other metals may be suitable, such as nickel, aluminum, or alloys thereof. The conductive features disclosed herein, such as the conductive features 1006a and 1006b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1002, 1004, as shown, the orientations of one or more conductive features 1006a, 1006b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1006b in the bonding layer 1008b (and/or at least one internal conductive feature, such as a BEOL feature) of the upper element 1004 may be tapered or narrowed upwardly, away from the bonding surface 1012b. By way of contrast, at least one conductive feature 1006a in the bonding layer 1008a (and/or at least one internal conductive feature, such as a BEOL feature) of the lower element 1002 may be tapered or narrowed downwardly, away from the bonding surface 1012a. Similarly, any bonding layers (not shown) on the backsides 1016a, 1016b of the elements 1002, 1004 may taper or narrow away from the backsides, with an opposite taper orientation relative to front side conductive features 1006a, 1006b of the same element.

As described above, in an anneal phase of hybrid bonding, the conductive features 1006a, 1006b can expand and contact one another to form a metal-to-metal direct bond. In some embodiments, the materials of the conductive features 1006a, 1006b of opposite elements 1002, 1004 can interdiffuse during the annealing process. In some embodiments, metal grains grow into each other across the bond interface 1018. In some embodiments, the metal is or includes copper, which can have grains oriented along the 1011 crystal plane for improved copper diffusion across the bond interface 1018. In some embodiments, the conductive features 1006a and 1006b may include nanotwinned copper grain structure, which can aid in merging the conductive features during anneal. There is substantially no gap between the non-conductive bonding layers 1008a and 1008b at or near the bonded conductive features 1006a and 1006b. In some embodiments, a barrier layer may be provided under and/or laterally surrounding the conductive features 1006a and 1006b (e.g., which may include copper). In other embodiments, however, there may be no barrier layer under the conductive features 1006a and 1006b.

The embodiments discussed above are intended to be illustrative and not limiting. One skilled in the art would appreciate that individual aspects of the displays, display devices, and methods discussed herein may be omitted, modified, combined, and/or rearranged without departing from the scope of the disclosure.

1. A display device comprising:
a substrate comprising one or more LEDs and one or more waveguides, wherein each LED is capable of emitting light in a first direction towards a corresponding waveguide, and the corresponding waveguide is capable of reflecting the emitted light in a second direction towards a viewing surface of the display device.

2. The display device of claim 1, wherein the substrate comprises a multilayer stack with an opening formed therein and a waveguide disposed in the opening, the multilayer stack comprising an LED and light emitted from the LED is guided by the waveguide towards the viewing surface of the display device.

3. The display device of claim 1, wherein the substrate comprises:
a first multilayer stack with a first opening formed therein and a first waveguide disposed in the first opening, the first multilayer stack comprising a first LED and light emitted from the first LED is guided by the first waveguide towards the viewing surface of the display device; and
a second multilayer stack overlaying the first multilayer stack, the second multilayer stack with a second opening formed therein and a second waveguide disposed in the second opening, the second multilayer stack comprising a second LED and light emitted from the second LED is guided by the second waveguide towards the viewing surface of the display device.

4. The display device of claim 3, further comprising a third multilayer stack overlaying the second multilayer stack with a third opening formed therein and a third waveguide disposed in the third opening, the third multilayer stack comprising a third LED and light emitted from the third LED is guided by the third waveguide towards the viewing surface of the display device.

5. The display device of claim 3, further comprising another substrate overlaying the second multilayer stack with a third opening formed therein and a third waveguide disposed in the third opening, wherein light emitted by the first and second multilayer stack exits the display device through the third waveguide.

6. The display device of claim 5, wherein the second multilayer stack is directly bonded to the vertically adjacent substrate without the use of an intervening adhesive.

7. The display device of claim 3, wherein each of the multilayer stacks and/or the respective waveguides are directly bonded to a vertically adjacent multilayer stack and/or waveguide without use of an intervening adhesive.

8. The display device of claim 3, wherein each multilayer stack comprises:
an active layer that is capable of emitting a light of a different color from another multilayer stack.

9. The display device of claim 8, wherein each multilayer stack further comprises:
a light guide layer disposed on the top and bottom of the active layer, wherein the light guide layers each have an index of refraction less than an index refraction of the active layer.

10. The display device of claim 9, wherein each multilayer stack further comprises:
a metallization layer disposed on the outward facing sides of each light guide layer.

11. The display device of claim 3, wherein each waveguide comprises an oxide or a dielectric material.

12. The display device of claim 3, wherein the first waveguide further comprises a reflective film.

13. The display device of claim 8, wherein the second waveguide comprises a dichroic film tuned to transmit light emitted from the active layer of the first multilayer stack and reflect light emitted from the active layer of the second multilayer stack towards a viewing surface of the display device.

14. The display device of claim 4, wherein:
each multilayer stack comprises an active layer that is capable of emitting a light of a different color from another multilayer stack; and
the third waveguide further comprises a dichroic film tuned to transmit light emitted from the active layers of the first and second multilayer stack and reflect light emitted from the active layer of the third multilayer stack towards a viewing surface of the display device.

15. The display device of claim 14, wherein a pixel comprises a combination of light emitted from the active layers of the first, second, and third multilayer stacks.

16. The display device of claim 15, wherein each pixel further comprises a lens disposed on top the third multilayer stack to shape light emitted from the first, second, and third multilayer stacks.

17. The display device of claim 15, wherein each pixel comprises an intra-pixel separation disposed between each pixel.

18. The display device of claim 3, wherein the multilayer stacks and respective waveguides have different orientations to one another.

19. A method for forming a display device, the method comprising:
providing a first substrate comprising one or more LEDs capable of emitting light in a first direction towards an edge of the display device, wherein a viewing surface of the display device is in a second direction;
providing a second substrate comprising one or more control devices; and
hybrid bonding the first substrate to the second substrate to electrically connect the one or more LEDs to the one or more control devices.

20. The method of claim 19, wherein:
the one or more LEDs comprise a plurality of LEDs; and
providing the first substrate comprises:
providing a multilayer stack; and
patterning the multilayer stack to form the plurality of LEDs.

21-36. (canceled)
